(19) United States
(12) Patent Application Publication
(10) Pub. No.: US 2026/0314464 A1
(43) Pub. Date: Oct. 8, 2026

(54) SEMICONDUCTOR DEVICE AND VEHICLE

(71) Applicant: FUJI ELECTRIC CO., LTD., Kawasaki-shi (JP)

(72) Inventor: Tomohiro ISONO, Kawasaki-shi (JP)

(73) Assignee: FUJI ELECTRIC CO., LTD., Kawasaki-shi (JP)

(21) Appl. No.: 19/633,052

(22) Filed: Mar. 30, 2026

(30) Foreign Application Priority Data
Apr. 2, 2025 (JP) 2025-060896

(51) Int. Cl. H10W 72/60; H10W 90/00; H10W 40/20; H10W 72/00

(52) U.S. Cl. CPC H10W 72/634; H10W 72/646; H10W 90/734; H10W 90/767; H10W 40/235; H10W 72/886

(57) ABSTRACT

A semiconductor device, including: a semiconductor element, having a plurality of metal layers stacked on a semiconductor layer, and an insulating layer formed between the metal layers in a top view thereof and extending in an extending direction; and a metal wiring board having a bonded portion bonded to the metal layers via a bonding material. The bonded portion has a bonded surface facing the metal layers, a recess formed in the bonded surface to separate the bonded surface into a plurality of portions; and a protrusion located immediately adjacent to the recess and protruding from the bonded surface. The recess faces the insulating layer and extends in the extending direction. The protrusion extends along the recess. An air passage, which is free of contact with the bonding material, is formed within the recess and is continuous from one end to another end in the extending direction in the recess.

### CROSS-REFERENCE TO RELATED APPLICATIONS

This application is based upon and claims the benefit of priority to Japanese Patent Application No. 2025-060896, filed on Apr. 2, 2025, the entire contents of which are incorporated herein by reference.

### BACKGROUND OF THE INVENTION

### 1. Technical Field

The present invention relates to a semiconductor device and a vehicle.

### 2. Description of the Related Art

A semiconductor device used in a power conversion device such as an inverter device includes a semiconductor device in which a main electrode exposed on one surface of a semiconductor element and a metal wiring board are bonded by a bonding material such as solder. Some semiconductor elements used in this type of semiconductor device include a semiconductor element in which an exposed surface of a main electrode to be bonded to a single metal wiring board is divided into a plurality of regions by an insulating layer (for example, WO 2019/244492 A, WO 2021/075220 A, and JP 2025 014321 A). In addition, when a semiconductor element is mounted on a lead frame by Pb-free solder, solder wettability is improved such that soldering reliability can be secured (for example, JP 2009 054690 A).

### SUMMARY OF THE INVENTION

When the exposed surface of the main electrode of the semiconductor element to be bonded to the single metal wiring board is divided into a plurality of regions by the insulating layer, the melted bonding material on the insulating layer may scatter and adhere to an unintended place in the process of bonding the metal wiring board and the main electrode of the semiconductor element. The bonding material adhering to and remaining in the unintended place can cause a product defect such as a malfunction of the semiconductor device.

The present invention has been made in view of such a point, and an object of the present invention is to prevent occurrence of product defects due to scattering of a bonding material used to bond a main electrode of a semiconductor element and a metal wiring board.

A semiconductor device according to one aspect of the present invention includes: a semiconductor element in which a plurality of metal layers adjacent to each other with an insulating layer interposed therebetween is exposed on a first surface; and a metal wiring board having a bonded portion bonded to the plurality of metal layers of the semiconductor element via a bonding material. The bonded portion of the metal wiring board has a first main surface facing the first surface of the semiconductor element and a second main surface opposite to the first main surface, wherein the first main surface of the bonded portion includes a plurality of bonded surfaces facing the plurality of metal layers, a recess located between bonded surfaces adjacent to each other and recessed from the bonded surfaces to the side of the second main surface, and a protrusion located between the bonded surfaces and the recess and protruding from the bonded surfaces to the side of the first surface of the semiconductor element. The recess on the first main surface of the bonded portion extends in an extending direction of the insulating layer at a position facing the insulating layer on the first surface of the semiconductor element, and the protrusion on the first main surface of the bonded portion extends along a boundary between the bonded surfaces and the recess. A region not in contact with the bonding material within the recess is continuous from one end to another end in the extending direction in the recess.

According to the present invention, it is possible to prevent occurrence of a malfunction of a semiconductor device due to scattering of a bonding material that bonds a main electrode of a semiconductor element and a conductor plate.

### BRIEF DESCRIPTION OF THE DRAWINGS

FIG. 1 is a top view showing a configuration example of a semiconductor device according to an embodiment;

FIG. 2 is a cross-sectional side view showing the configuration example of the semiconductor device cut at a position indicated by an alternate long and short dash line A-A’ in FIG. 1;

FIG. 3 is a diagram showing a configuration example of an inverter circuit to which the semiconductor device of FIG. 1 is applied;

FIG. 4 is a top view showing a configuration example of a top electrode of a semiconductor element bonded to a metal wiring board according to the first embodiment;

FIG. 5 is a cross-sectional view showing an example of a bonded state between a main electrode of the semiconductor element and the metal wiring board at a position indicated by an alternate long and short dash line B-B’ in FIG. 4;

FIG. 6 is a cross-sectional side view showing an example of the bonded state between the main electrode of the semiconductor element and the metal wiring board at a position indicated by an alternate long and short dash line C-C’ in FIG. 4;

FIG. 7 is a top view illustrating a relationship between an insulating layer between the main electrodes of the semiconductor element according to the first embodiment and a recess and a protrusion of the metal wiring board;

FIG. 8 is a front view illustrating the shapes of the recess and the protrusion of the metal wiring board;

FIG. 9 is a perspective view illustrating an example of a method of providing a recess and a protrusion in a joint portion of a metal wiring board;

FIGS. 10A and 10B are cross-sectional views illustrating an example of a method of forming a recess of a metal wiring board;

FIG. 11 is a view illustrating an example of a method of bonding a main electrode of a semiconductor element and a metal wiring board;

FIG. 12 is a partial top view illustrating a problem that occurs at the time of bonding a plurality of main electrodes separated by an insulating layer and a conventional metal wiring board;

FIG. 13 is a cross-sectional side view illustrating an example in which a bonding material between a semiconductor element and a conventional metal wiring board scatters;

FIG. 14 is a top view illustrating a relationship between an insulating layer between main electrodes of a semiconductor element according to a second embodiment and a recess and a protrusion of a metal wiring board;

FIG. 15A is a front view illustrating an example of a shape of a protrusion of a metal wiring board according to a third embodiment, and FIG. 15B is a front view for explaining an example of a shape of a protrusion of a metal wiring board according to a fourth embodiment;

FIGS. 16A and 16B are cross-sectional views illustrating an example of a method of forming a metal wiring board according to a fifth embodiment;

FIG. 17A is a front view illustrating an example of a shape of a metal wiring board according to a sixth embodiment, and FIG. 17B is a cross-sectional view illustrating an example of a method of forming the metal wiring board according to the sixth embodiment;

FIG. 18 is an exploded top view illustrating a relationship between main electrodes of a semiconductor element and a metal wiring board according to a seventh embodiment;

FIG. 19 is a bottom view illustrating a configuration example of a first main surface of the metal wiring board according to the seventh embodiment;

FIG. 20A is a view of the metal wiring board as viewed from an arrow E in FIG. 19, and FIG. 20B is a cross-sectional side view of the metal wiring board at a position indicated by an alternate long and short dash line F-F’ in FIG. 19;

FIG. 21 is a bottom view illustrating a modified example of the metal wiring board according to the seventh embodiment; and

FIG. 22 is a schematic plan view showing an example of a vehicle to which the semiconductor device according to the present invention is applied.

### DETAILED DESCRIPTION

Hereinafter, embodiments of the present invention will be described in detail with reference to the drawings. Note that the X axis, the Y axis, and the Z axis in each of the drawings to be referred to are illustrated for the purpose of defining a plane and a direction in the exemplified semiconductor device or the like. The X axis, the Y axis, and the Z axis are orthogonal to each other and form a right-handed system. In the following description, a direction parallel to the X axis is referred to as an X direction, a direction parallel to the Y axis is referred to as a Y direction, and a direction parallel to the Z axis is referred to as a Z direction. In addition, in a case where each of the X direction, the Y direction, and the Z direction is associated with a direction of an arrow (positive or negative) of the X axis, the Y axis, and the Z axis illustrated, a “positive side” or a “negative side” is attached.

In the present specification, the Z direction may be referred to as a vertical direction. In the present specification, “on” and “upper” are intended to be on the positive side in the Z direction with respect to the reference surface, member, position, and the like, and “under” and “lower” are intended to be on the negative side in the Z direction with respect to the reference surface, member, position, and the like. For example, when it is described that “the member B is disposed on the member A”, the member B is disposed on the positive side in the Z direction as viewed from the member A. Further, when an “upper surface of the member A” is described, the surface is positioned at the end of the member A on the positive side in the Z direction and faces the positive side in the Z direction. In the present specification, “top view” is intended as a plan view when a target article (for example, a semiconductor device or the like) is viewed from the positive side in the Z direction. In the present specification, “side view” is intended as a plan view when a target article is viewed from the negative side in the X direction or the positive side in the X direction, and the plan view when viewed from the negative side in the X direction may be referred to as a “left side view”, and the plan view when viewed from the positive side in the X direction may be referred to as a “right side view”. These directions and surfaces are words used for convenience of description, and the correspondence relationship with each of the directions of the X axis, the Y axis, and the Z axis may change depending on the attachment posture of a semiconductor device and the like. For example, in the present specification, a surface of a semiconductor element facing a wiring board is referred to as a lower surface, and a surface opposite to the lower surface is referred to as an upper surface, but the present invention is not limited thereto, and a surface facing the wiring board may be referred to as an upper surface, and a surface opposite thereto may be referred to as a lower surface. The lower surface and the upper surface of the semiconductor element may be referred to as side surfaces. In addition, the aspect ratio and the magnitude relationship between members in each drawing are merely schematically represented, and do not necessarily coincide with the relationship in a semiconductor device or the like actually manufactured. For convenience of description, it is also assumed that the magnitude relationship between members is exaggerated.

Furthermore, the semiconductor device exemplified in the following description may be applied to, for example, a power conversion device such as a vehicular or industrial inverter device. Therefore, in the following description, detailed description of the same or similar configuration, function, operation, manufacturing method, and the like as those of the known semiconductor device will be omitted.

### Configuration Example of Semiconductor Device

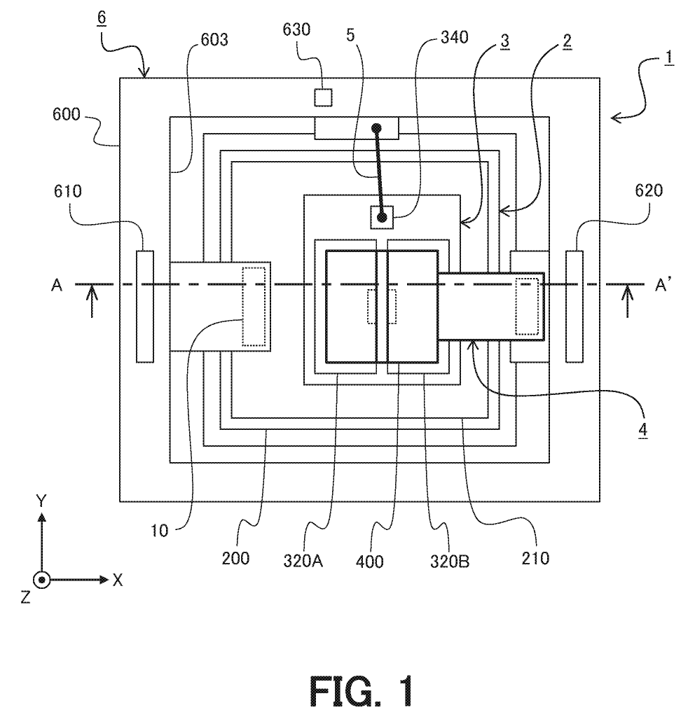

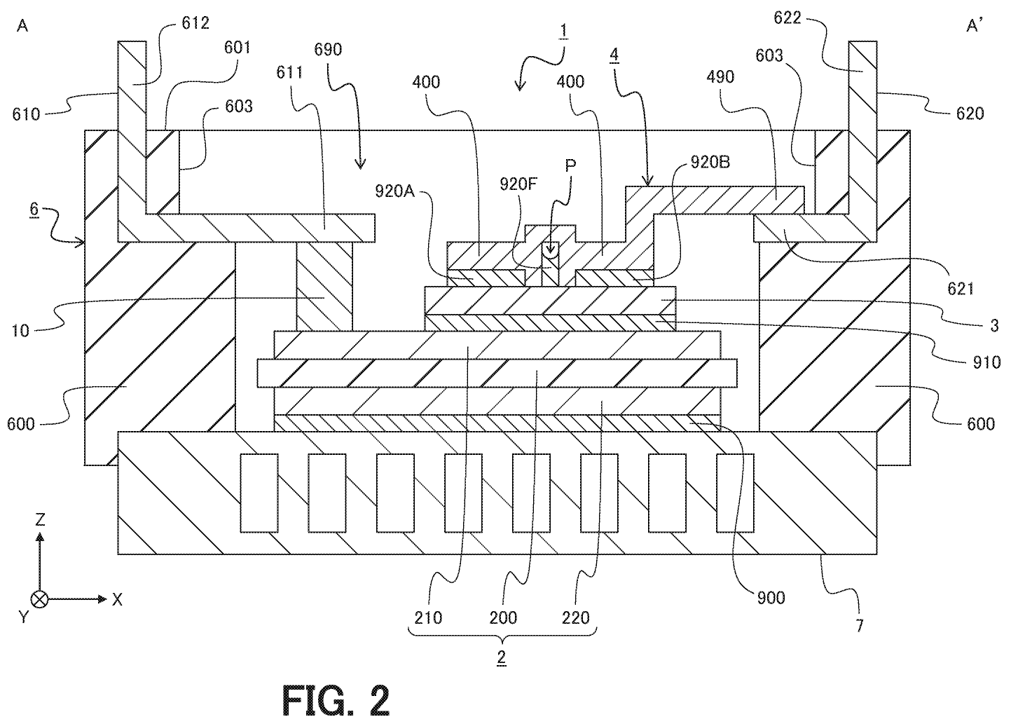

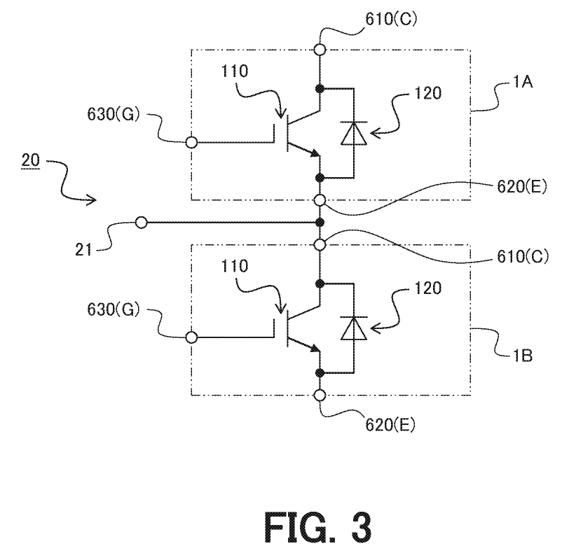

FIG. 1 is a top view showing a configuration example of a semiconductor device according to an embodiment. FIG. 2 is a cross-sectional side view showing the configuration example of the semiconductor device cut at a position indicated by an alternate long and short dash line A-A’ in FIG. 1. FIG. 3 is a diagram showing a configuration example of an inverter circuit to which the semiconductor device of FIG. 1 is applied. In FIG. 2, a sealing material for sealing a semiconductor element or the like is omitted.

The semiconductor device 1 illustrated in FIG. 1 and FIG. 2 includes a wiring board 2, a semiconductor element 3, a metal wiring board 4, a bonding wire 5, a case 6, and a cooler 7. The semiconductor device 1 is used, for example, as a circuit component for forming an inverter circuit. As an example, FIG. 3 illustrates a half-bridge inverter circuit 20 formed using two semiconductor devices 1A and 1B. The first semiconductor device 1A and the second semiconductor device 1B in FIG. 3 can be the semiconductor device 1 illustrated in FIG. 1 and FIG. 2. Each of the semiconductor devices 1A and 1B includes an insulated gate bipolar transistor (IGBT) element 110 that is a switching element, and a diode element 120 connected in antiparallel to the IGBT element 110. The diode element 120 may be referred to as a freewheeling diode (FWD). In the semiconductor device 1 exemplified in the present specification, the semiconductor element 3 may be a reverse conducting (RC)-IGBT element in which the IGBT element 110 and the diode element 120 are integrated. In the half-bridge inverter circuit 20, an emitter terminal 620 of the first semiconductor device 1A and a collector terminal 610 of the second semiconductor device 1B are electrically connected to an intermediate terminal 21.

The wiring board 2 includes an insulating substrate 200, a first conductive layer 210 provided on an upper surface of the insulating substrate 200, and a second conductive layer 220 provided on a lower surface of the insulating substrate 200. The wiring board 2 can be, for example, a direct copper bonding (DCB) substrate or an active metal brazing (AMB) substrate. The wiring board 2 may be referred to as a wiring substrate, a laminated substrate, or the like. The insulating substrate 200 may be, for example, a ceramic substrate formed of a ceramic material such as aluminum oxide (Al₂O₃), aluminum nitride (AlN), silicon nitride (Si₃N₄), or a composite material of aluminum oxide (Al₂O₃) and zirconium oxide (ZrO₂). The insulating substrate 200 is not limited to a ceramic substrate. The insulating substrate 200 may be, for example, a substrate obtained by molding an insulating resin such as an epoxy resin, a substrate obtained by impregnating a base material such as glass fiber with an insulating resin, a substrate obtained by coating the surface of a flat plate-shaped metal core with an insulating resin, or the like. The first conductive layer 210 is one of wiring components that electrically connects a lower electrode (for example, the collector electrode of the IGBT element 110 of FIG. 3) of the semiconductor element 3 disposed on the wiring board 2 and a collector terminal 610 of the case 6. The second conductive layer 220 is a heat conducting component for dissipating heat generated by the semiconductor element 3 to the outside of the semiconductor device 1. The first conductive layer 210 and the second conductive layer 220 are formed using, for example, a metal plate such as copper or aluminum, a metal foil, or the like. The conductive layer in the wiring board 2 may be referred to as a conductor layer, a conductor plate, or the like.

For example, as illustrated in FIG. 2, the wiring board 2 is disposed on the upper surface of the cooler 7. The second conductive layer 220 of the wiring board 2 and the cooler 7 are bonded by a bonding material 900 such as solder. Instead of the bonding material 900, a thermal conductive material such as thermal grease or thermal compound may be used. The cooler 7 may have any configuration that is thermally connected to the semiconductor element 3 and can dissipate heat generated by the semiconductor element 3 during operation to the outside of the semiconductor device 1 and is not limited to a specific configuration. The cooler 7 may include, for example, a flat plate-shaped base member to which the wiring board 2 is bonded, and a water jacket attached below the base member. In the cooler 7, fins may be provided in a refrigerant flow path defined by the base member and the water jacket (refer to FIG. 2). Note that the cooler 7 may be any component in the semiconductor device 1. The semiconductor device 1 may include a member having high thermal conductivity such as a metal plate instead of the cooler 7, and the wiring board 2 may be bonded to the upper surface of the member.

The semiconductor element 3 disposed on the upper surface of the wiring board 2 may be the above-described RC-IGBT element, and a first main electrode (collector electrode) (not illustrated) exposed on the lower surface is bonded to the first conductive layer 210 of the wiring board 2 by a bonding material 910. As illustrated in FIG. 1, two second main electrodes 320A and 320B and a control electrode 340 are exposed on the upper surface of the semiconductor element 3. The second main electrodes 320A and 320B exposed on the upper surface of the semiconductor element 3 are emitter electrodes of the IGBT element 110 and are bonded to a first joint 400 of the metal wiring board 4 by bonding materials 920A and 920B. The first joint 400 is an example of a portion (bonded portion) of the metal wiring board 4 bonded to a plurality of metal layers of the semiconductor element 3 using a bonding material. The metal wiring board 4 is one of wiring components electrically connecting the second main electrodes 320A and 320B of the semiconductor element 3 to the emitter terminal 620 of the case 6 and may be referred to as a lead or the like. In the following description, the second main electrodes 320A and 320B of the semiconductor element 3 bonded to the metal wiring board 4 are referred to as emitter electrodes 320A and 320B, respectively.

The case 6 is a component disposed on the upper surface of the cooler 7 to surround the semiconductor element 3 and the like, and includes a resin member 600, a collector terminal 610, an emitter terminal 620, and a control terminal 630. The resin member 600 may be an annular member that defines a space 690 for accommodating the semiconductor element 3 and the like on the upper surface side of the cooler 7. The collector terminal 610, the emitter terminal 620, and the control terminal 630 are wiring components electrically connected to the collector, the emitter, and the gate of the semiconductor element 3 (IGBT element 110), and are integrated with the resin member 600.

The collector terminal 610 of the case 6 is a terminal electrically connected to the collector electrode of the semiconductor element 3, and includes an inner terminal portion 611 extending from an inner peripheral wall surface 603 of the resin member 600 into the space 690 and an outer terminal portion 612 extending from the upper surface 601 of the resin member 600 to the outside of the semiconductor device 1. The inner terminal portion 611 of the collector terminal 610 is electrically connected to the first conductive layer 210 via a conductive block 10 disposed on the first conductive layer 210 of the wiring board 2, for example. The conductive block 10 is bonded to each of the first conductive layer 210 of the wiring board 2 and the inner terminal portion 611 of the collector terminal 610 by, for example, a bonding material (not illustrated). The conductive block 10 may be integrally formed with the first conductive layer 210 of the wiring board 2. The method of electrically connecting the first conductive layer 210 of the wiring board 2 and the inner terminal portion 611 of the collector terminal 610 is not limited to the method using the conductive block 10. For example, the inner terminal portion 611 of the collector terminal 610 may be bent downward, and the inner terminal portion 611 and the first conductive layer 210 of the wiring board 2 may be bonded to each other by a bonding material, ultrasonic bonding, laser welding, or the like.

The emitter terminal 620 of the case 6 is a terminal electrically connected to the emitter electrodes 320A and 320B of the semiconductor element 3, and includes an inner terminal portion 621 extending from an inner peripheral wall surface 603 of the resin member 600 into the space 690 and an outer terminal portion 622 extending from the upper surface 601 of the resin member 600 to the outside of the semiconductor device 1. The inner terminal portion 621 of the emitter terminal 620 is electrically connected to the emitter electrodes 320A and 320B of the semiconductor element 3 via the metal wiring board 4, for example. In the metal wiring board 4, the first joint 400 is bonded to the emitter electrodes 320A and 320B of the semiconductor element 3 by the bonding materials 920A and 920B, and the second joint 490 is bonded to the inner terminal portion 621 of the emitter terminal 620 by a bonding material (not illustrated), ultrasonic bonding, laser welding, or the like.

The control terminal 630 of the case 6 is a terminal electrically connected to the control electrode 340 of the semiconductor element 3, and includes an inner terminal portion extending from the inner peripheral wall surface 603 of the resin member 600 into the space 690 and an outer terminal portion extending from the upper surface 601 of the resin member 600 to the outside of the semiconductor device 1. An inner terminal portion of the control terminal 630 is electrically connected to the control electrode 340 of the semiconductor element 3 by the bonding wire 5.

The semiconductor device 1 described above with reference to FIG. 1 and FIG. 2 is merely an example of a semiconductor device using the metal wiring board 4 according to the embodiment described below. The semiconductor device 1 may include, for example, a plurality of semiconductor elements 3, and the half-bridge inverter circuit 20 illustrated in FIG. 3 may be formed. A plurality of half-bridge inverter circuits 20 may be formed in one semiconductor device 1. In the semiconductor device 1, a circuit different from the half-bridge inverter circuit 20 may be formed. In the semiconductor device 1 using the metal wiring board 4 according to the embodiment, the electrode of the semiconductor element 3 bonded to the first joint 400 of the metal wiring board 4 is divided into a plurality of metal layers by an insulating layer and exposed.

### First Embodiment

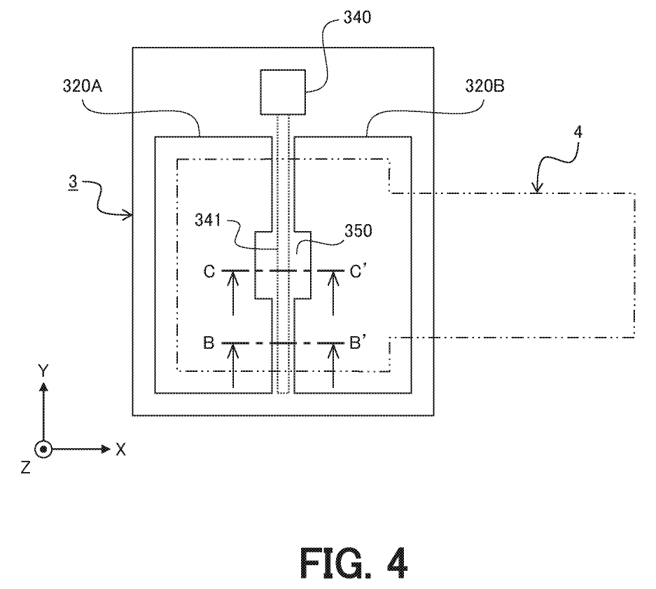

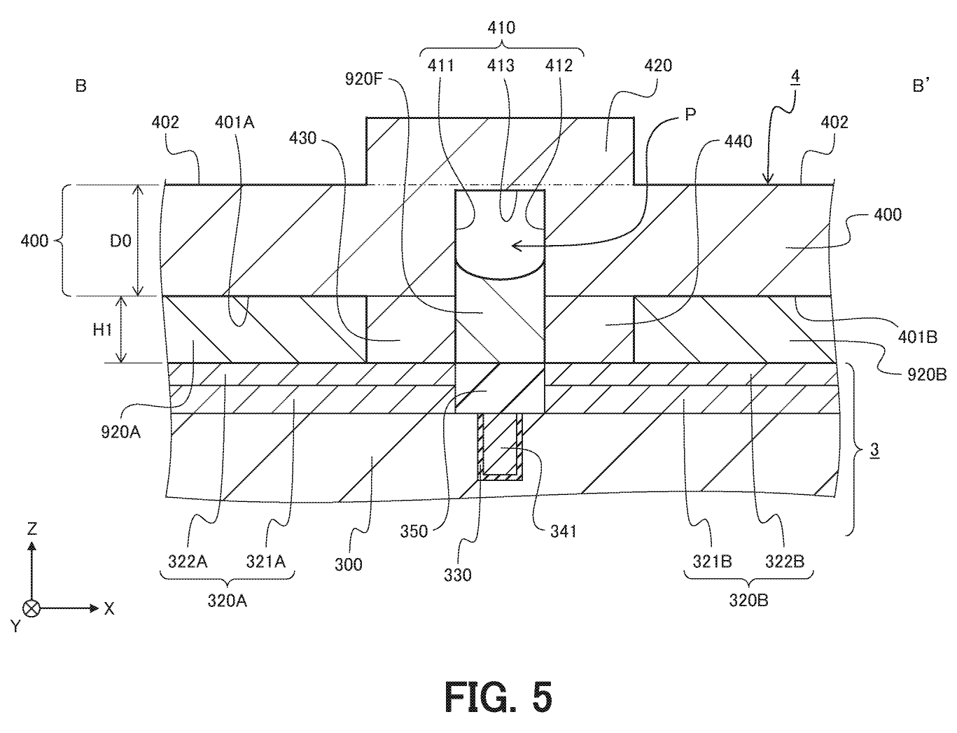

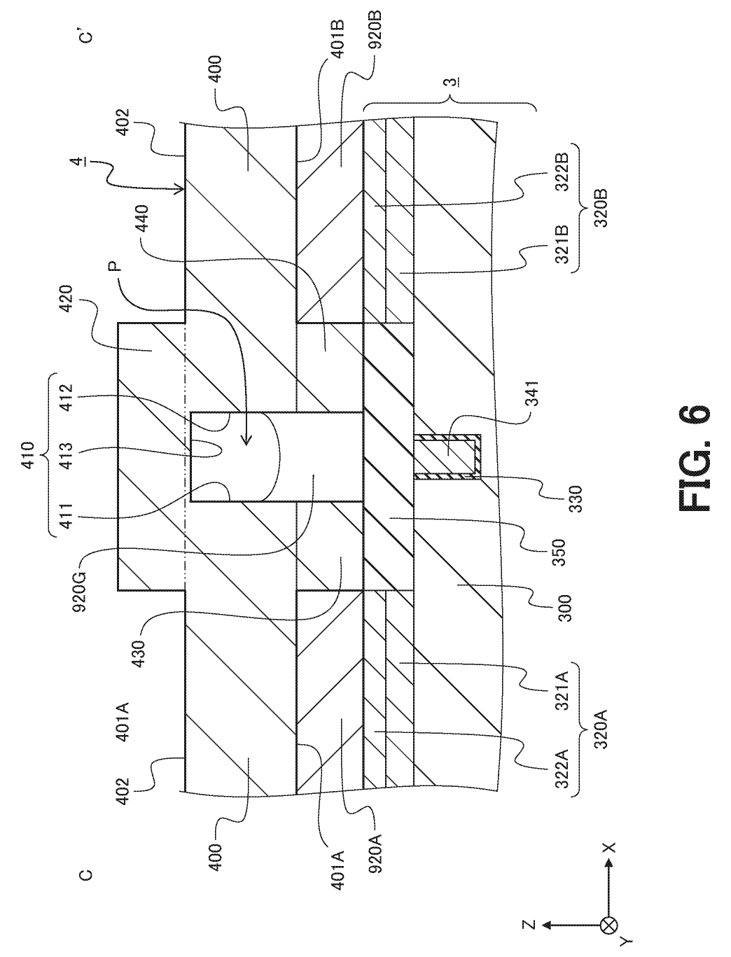

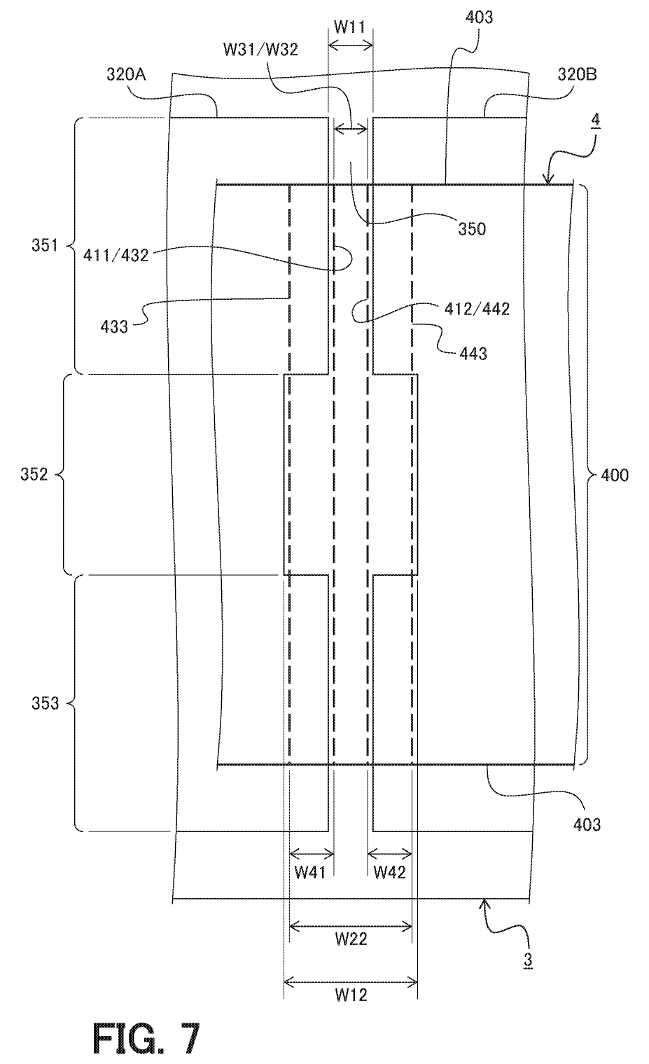

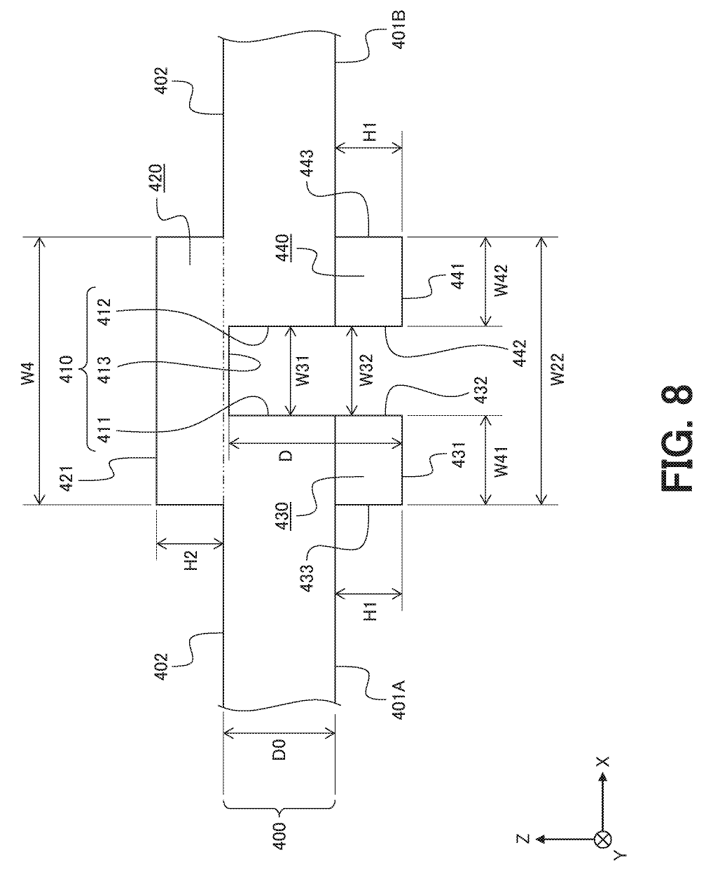

FIG. 4 is a top view showing a configuration example of a top electrode of the semiconductor element bonded to the metal wiring board according to the first embodiment. FIG. 5 is a cross-sectional view showing an example of a bonded state between a main electrode of the semiconductor element and the metal wiring board at a position indicated by an alternate long and short dash line B-B’ in FIG. 4. FIG. 6 is a cross-sectional side view showing an example of the bonded state between the main electrode of the semiconductor element and the metal wiring board at a position indicated by an alternate long and short dash line C-C’ in FIG. 4. FIG. 7 is a top view illustrating a relationship between an insulating layer between the main electrodes of the semiconductor element according to the first embodiment and a recess and a protrusion of the metal wiring board. FIG. 8 is a front view illustrating the shapes of the recess and the protrusion of the metal wiring board. In FIG. 7 and other drawings, in a case where a single line, a range, or the like illustrated in the drawing can be associated with a plurality of constituent elements, reference signs, symbols, and the like attached to the plurality of constituent elements are written together using a slash (/). For example, a broken line denoted by a reference sign “411/432” in FIG. 7 represents a wall surface 411 of a recess 410 and an inner side surface 432 of a protrusion 430 in FIG. 8.

In the semiconductor element 3 exemplified in the present specification, as illustrated in FIG. 4 to FIG. 6, two emitter electrodes 320A and 320B divided by an insulating layer 350 are provided on the upper surface of a semiconductor layer 300. A control signal line 341 connected to the control electrode 340 extends in a region between the first emitter electrode 320A and the second emitter electrode 320B in a plan view (XY plan view) of the upper surface of the semiconductor layer 300. When the IGBT element formed in the semiconductor element 3 has a trench gate structure, the control signal line 341 is provided in a groove (trench) formed on the upper surface of the semiconductor layer 300 via an insulating layer (gate oxide film) 330. Although not illustrated in FIG. 4, the control signal line 341 is connected to a gate of an IGBT element extending below the first emitter electrode 320A (in the -X direction) and a gate of an IGBT element extending below the second emitter electrode 320B (in the +X direction), and may be called a gate runner. The control signal line 341 is covered with the insulating layer 350 that separates the first emitter electrode 320A and the second emitter electrode 320B. In each of the emitter electrodes 320A and 320B, for example, as shown in FIG. 5 and FIG. 6, a first metal layer 321 and a second metal layer 322 are laminated. Each of the emitter electrodes 320A and 320B may be a single metal layer, or three or more metal layers may be laminated.

In the semiconductor layer 300, a region functioning as an IGBT element and a region functioning as a diode element (FWD) are formed by doping a known semiconductor substrate with a predetermined impurity at a predetermined concentration. In addition, the semiconductor layer 300 may be provided with a region functioning as a diode for a temperature sensor. The semiconductor substrate can be a silicon (Si) substrate but is not limited to a substrate of a specific semiconductor material. The semiconductor substrate may be, for example, a substrate using a wide band gap semiconductor such as a silicon carbide (SiC) substrate or a gallium nitride (GaN) substrate. The IGBT element formed in the semiconductor element 3 is not limited to the above-described trench gate structure. The IGBT element may have, for example, a planar structure. The switching element formed in the semiconductor element 3 is not limited to the IGBT element and may be a power metal oxide semiconductor field effect transistor (MOSFET) element, a bipolar junction transistor (BJT) element, or the like. When the switching element is a MOSFET element, the main electrode on the lower surface side of the semiconductor element 3 may be referred to as a drain electrode, and the main electrode on the upper surface side may be referred to as a source electrode. Furthermore, the diode element 120 connected in antiparallel to the switching element as an FWD can be, for example, a Schottky barrier diode (SBD) element, a junction barrier Schottky (JBS) diode element, a merged PN Schottky (MPS) diode element, a PN diode element, or the like.

FIG. 7 is an enlarged top view of a region where the insulating layer 350 between the first emitter electrode 320A and the second emitter electrode 320B extends and its periphery on the upper surface of the semiconductor element 3 exemplified in FIG. 4. In the insulating layer 350 of the illustrated semiconductor element 3, the width W12 of a second section 352, which is the central portion in the extending direction (Y direction), is greater than the width W11 of a first section 351 on the positive side in the Y direction and a third section 353 on the negative side in the Y direction with respect to the second section 352. In the second section 352, the above-described diode for a temperature sensor is provided. The width W12 of the second section 352 and the width W11 of the first section 351 and the third section 353 are not limited to specific values. In an example, the width W11 of the first section 351 and the third section 353 may be 0.166mm, and the width W12 of the second section 352 may be 0.520mm.

The first joint 400 of the metal wiring board 4 bonded to the emitter electrodes 320A and 320B of the semiconductor element 3 is disposed on the semiconductor element 3 in such a direction that a main surface (first main surface) on one end side in the plate thickness direction is a lower surface facing the semiconductor element 3 and a second main surface opposite thereto is an upper surface. The lower surface (first main surface) of the first joint 400 has bonded surfaces 401A and 401B facing the emitter electrodes 320A and 320B, which are metal layers to be bonded. In addition, the lower surface of the first joint 400 has a recess 410 that is located between the adjacent bonded surfaces 401A and 401B and recessed toward the upper surface (second main surface 402) from the positions of the bonded surfaces. Further, the lower surface of the first joint 400 is positioned between the bonded surface 401A and the recess 410 and between the bonded surface 401B and the recess 410 and has protrusions 430 and 440 protruding from the positions of the bonded surfaces toward the semiconductor element 3.

In the metal wiring board 4 according to the present embodiment, the recess 410 is formed from one end 403 to the other end 404 of the first joint 400 in the extending direction (Y direction) of the insulating layer 350 of the semiconductor element 3. The exemplified recess 410 has a rectangular cross section (refer to FIG. 8), and is formed to have a constant width W31 from one end 403 to the other end 404. The term “cross section” intends a cross section parallel to the ZX plane orthogonal to the extending direction (Y direction) of the recess 410. The width W31 (distance from one wall surface 411 to the other wall surface 412) of the recess 410 can be, for example, substantially the same as the width W11 of the first section 351 and the third section 353 in the insulating layer 350 of the semiconductor element 3. In FIG. 7, in order to make it easy to ascertain the dimension such as the width W11 regarding the insulating layer 350 of the semiconductor element 3 and the dimension such as the width W31 regarding the metal wiring board 4, the positions of the end in the width direction of the insulating layer 350 and the end in the width direction of the recess 410 (wall surfaces 411 and 412) are illustrated to be shifted from each other.

The first protrusion 430 and the second protrusion 440 of the metal wiring board 4 are each formed along the recess 410 from one end 403 to the other end 404 of the first joint 400 in the extending direction (Y direction) of the recess 410. The exemplified first protrusion 430 and second protrusion 440 have a rectangular cross section and are formed to have a constant spacing W32 from one end 403 to the other end 404. The spacing W32 can be a distance from the side surface 432 of the first protrusion 430 facing the second protrusion 440 to the side surface 442 of the second protrusion 440 facing the first protrusion 430. In the following description, the side surface 432 of the first protrusion 430 and the side surface 442 of the second protrusion 440 facing each other are referred to as an inner side surface 432 and an inner side surface 442, respectively. In one example, the spacing W32 may be substantially the same as the width W31 of the recess 410. In this example, the inner side surface 432 of the first protrusion 430 may be a surface obtained by extending the wall surface 411 of the recess 410, and the inner side surface 442 of the second protrusion 440 may be a surface obtained by extending the wall surface 412 of the recess 410.

The heights H1 of the first protrusion 430 and the second protrusion 440 (distances from the bonded surfaces 401A and 401B to the distal end surfaces 431 and 441) are set such that the bonding materials 920A and 920B have desired thicknesses. In one example, the height H1 of the first protrusion 430 and the second protrusion 440 can be, for example, 0.3mm. The width W41 of the first protrusion 430 and the width W42 of the second protrusion 440 are associated with the width W12 of the second section in the insulating layer 350 of the semiconductor element 3. In one example, the width W41 and the width W42 are set such that W41=W42 and W12=W22 (=W32+W41+W42). In this example, a distance W22 from the side surface 433 of the first protrusion 430 opposite to the inner side surface 432 to the side surface 443 of the second protrusion 440 opposite to the inner side surface 442 is substantially the same as the width W12 of the second section 352 in the insulating layer 350 of the semiconductor element 3.

As illustrated in FIG. 5, FIG. 6, and FIG. 8, the position of the bottom surface 413 of the recess 410 in the metal wiring board 4 according to the present embodiment can be a position closer to the upper surface 402 between the bonded surfaces 401A and 401B, which can be lower surfaces (first main surfaces) of the first joint 400, and the upper surface (second main surface) 402. The magnitude relationship between the distance D from the bottom surface 413 of the recess 410 to the distal end surface 431 of the first protrusion 430 and the distance D0+H1 from the upper surface 402 of the first joint 400 to the distal end surface 431 of the first protrusion 430 is not limited to a specific relationship. The magnitude relationship between the distance D and the distance D0+H1 is not limited to (H1<)D<D0+H1, but may be D=D0+H1, or in some cases D>D0+H1.

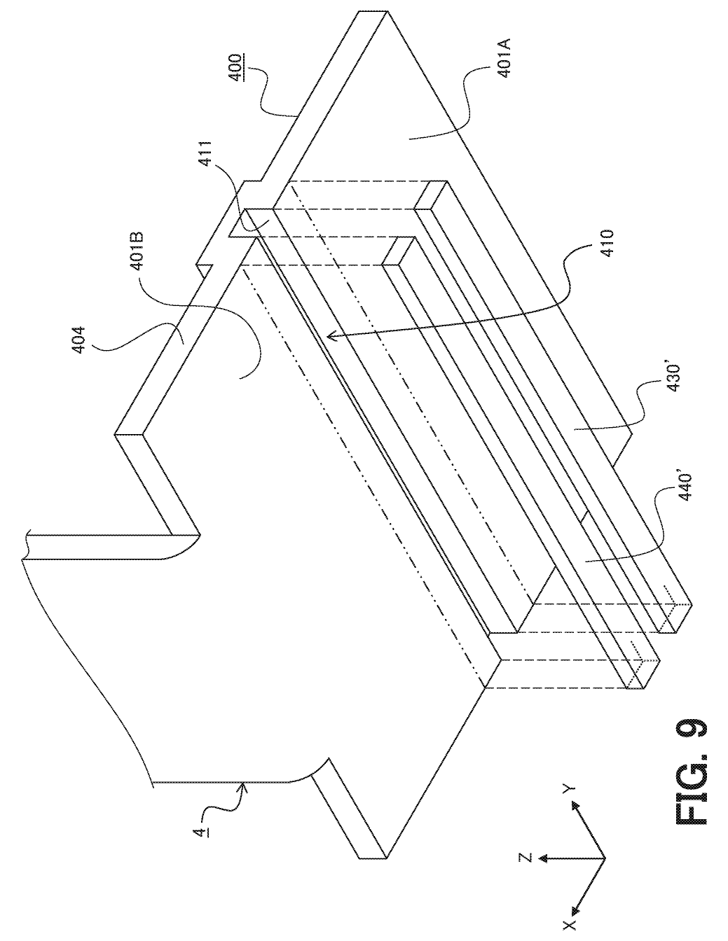

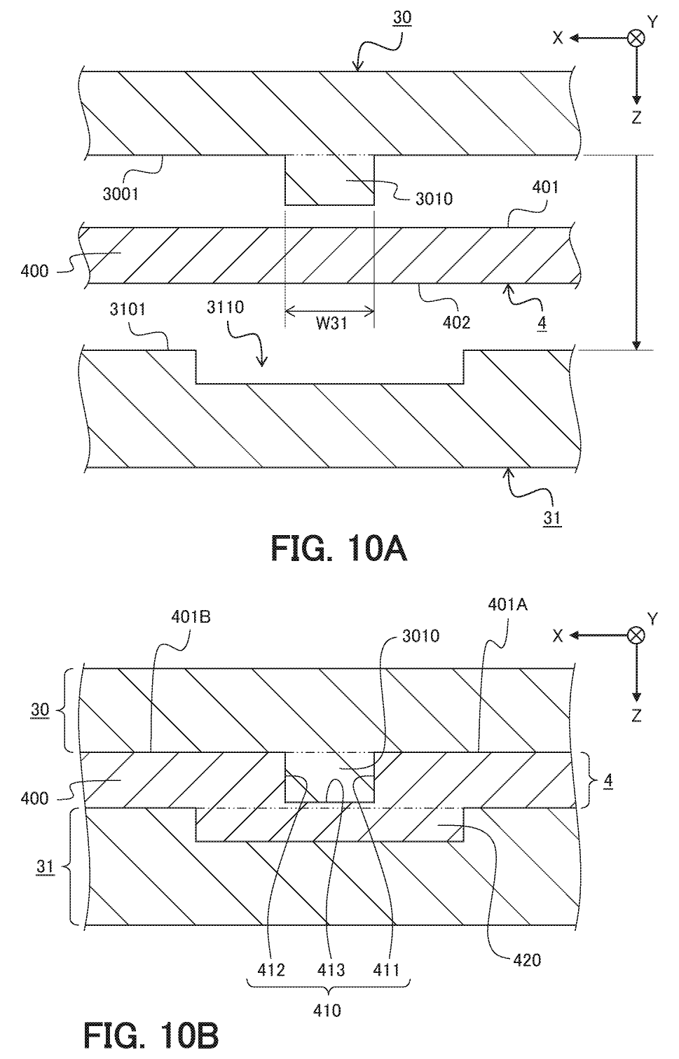

FIG. 9 is a perspective view illustrating an example of a method of providing a recess and a protrusion in a joint of a metal wiring board. FIG. 10A and FIG. 10B are cross-sectional views illustrating an example of a method of forming the recess of the metal wiring board.

For example, as illustrated in FIG. 9, the metal wiring board 4 according to the present embodiment can be manufactured by forming the recess 410 on the lower surface of the flat plate-shaped first joint 400 in the metal wiring board 4 and then joining two rod-shaped members 430’ and 440’ serving as the protrusions 430 and 440 to the lower surface of the first joint 400. The recess 410 can be formed on the lower surface of the first joint 400 in the process of manufacturing the metal wiring board 4 by known press processing. As an example, FIG. 10A and FIG. 10B illustrate an upper mold 30 having a protrusion 3010 for forming the recess 410 in the flat metal wiring board 4, and a lower mold 31 having a recess 3110 for molding a portion pushed out from the flat metal wiring board 4 by the protrusion 3010 of the upper mold 30. In this example, as illustrated in FIG. 5, FIG. 6, FIG. 8, and the like, the protrusion 420 corresponding to the recess 410 formed on the lower surface is formed on the upper surface (second main surface) 402 of the first joint 400. A height H2 and a width W4 (refer to FIG. 8) from the second main surface 402 to the distal end surface 421 of the protrusion 420 depend on the dimension of the recess 3110 of the lower mold 31 used to form the recess 410 of the metal wiring board 4. The process of forming the recess 410 is incorporated into a processing process of performing a series of processing for forming the metal wiring board 4 from a metal plate. The formation of the recess 410 may be performed simultaneously with other processing (for example, processing of bending the flat metal wiring board 4).

The two rod-shaped members 430’ and 440’ used to form the protrusions 430 and 440 are formed of the same kind of metal material as the material of the metal wiring board 4. The rod-shaped members 430’ and 440’ can be bonded to the lower surface of the first joint 400 in the metal wiring board 4 by a bonding material or by laser welding or the like. The method of providing the recess 410, the first protrusion 430, and the second protrusion 440 on the lower surface of the first joint 400 in the metal wiring board 4 is not limited to a specific method.

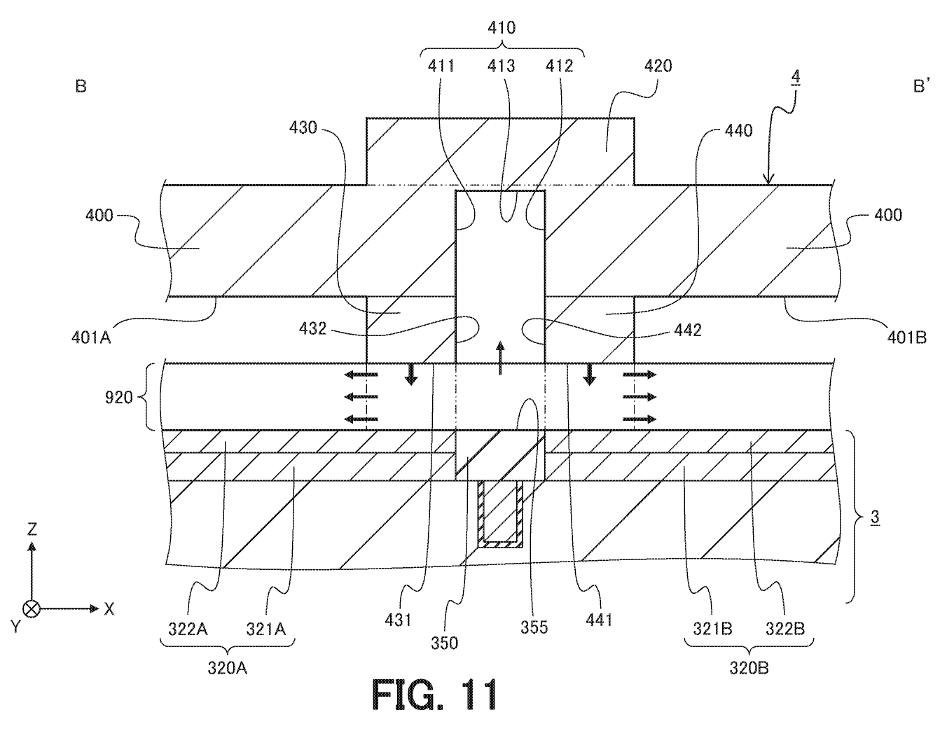

FIG. 11 is a diagram illustrating an example of a method of bonding a main electrode of the semiconductor element and the metal wiring board. Bonding between the metal wiring board 4 and the emitter electrodes 320A and 320B of the semiconductor element 3 according to the present embodiment is performed in a procedure similar to a known bonding process using a bonding material 920. For example, first, as shown in FIG. 11, one plate solder extending over the first emitter electrode 320A and the second emitter electrode 320B is disposed as the bonding material 920 at a predetermined position on the upper surface of the semiconductor element 3. Thereafter, for example, the first joint 400 of the metal wiring board 4 is disposed on the bonding material 920, and the bonding material 920 is heated and melted in a state in which a pressing load is applied to the first joint 400 from the upper surface. The bonding material 920 melted by heating has wettability with respect to the emitter electrodes 320A and 320B higher than wettability with respect to the insulating layer 350. Therefore, a portion of the melted bonding material 920 located on the insulating layer 350 tends to flow out to the side of the first emitter electrode 320A or the side of the second emitter electrode 320B. When the bonding material 920 is melted, the first protrusion 430 and the second protrusion 440 provided on the lower surface of the first joint 400 enter the bonding material 920. At this time, a portion of the bonding material 920 present below each of the protrusions 430 and 440 is promoted to flow toward the side of the bonded surfaces 401A and 401B due to the influence of the bonding material 920 that is about to flow to the side of the emitter electrode 320A or 320B from above the insulating layer 350. Finally, as illustrated in FIG. 5, FIG. 6, and the like, the distal end surface 431 of the first protrusion 430 and the distal end surface 441 of the second protrusion 440 are in contact with the upper surface of the semiconductor element 3. In this process, some of the bonding material 920 present below the recess 410 (on the insulating layer 350) and below each of the protrusions 430 and 440 passes between the first protrusion 430 and the second protrusion 440 and enters the recess 410. However, the first protrusion 430 and the second protrusion 440 serve as walls, and the bonding material 920A on the first emitter electrode 320A and the bonding material 920B on the second emitter electrode 320B enter the recess 410 to prevent the recess 410 from being filled with the bonding material. Therefore, by using the metal wiring board 4 of the present embodiment, it is possible to prevent the bonding material that has entered the recess 410, such as bonding materials 920F and 920G in the recess 410 shown in FIG. 5 and FIG. 6, from reaching the bottom surface 413 of the recess 410. Therefore, by using the metal wiring board 4 of the present embodiment, the inside of the recess 410 can be prevented from being filled with the bonding material 920, and an air passage P (refer to FIG. 5 and FIG. 6) communicating from one end 403 to the other end 404 in the extending direction can be provided in the recess 410. Note that the bonding material 920F in FIG. 5 and the bonding material 920G in FIG. 6 may be different portions in a single bonding material lump in the recess 410, or may be separate bonding material lumps in the recess 410.

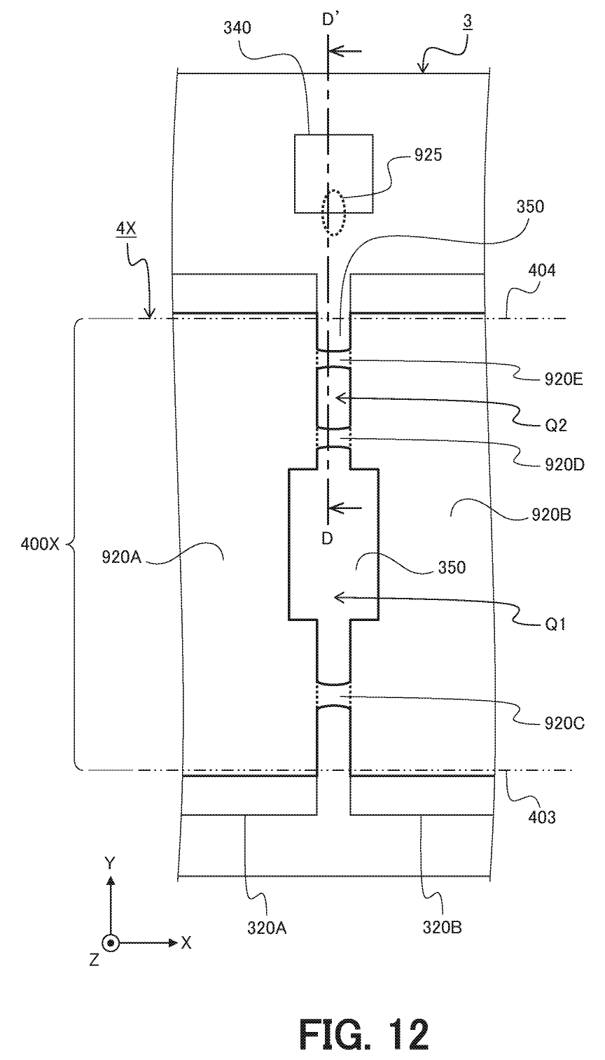

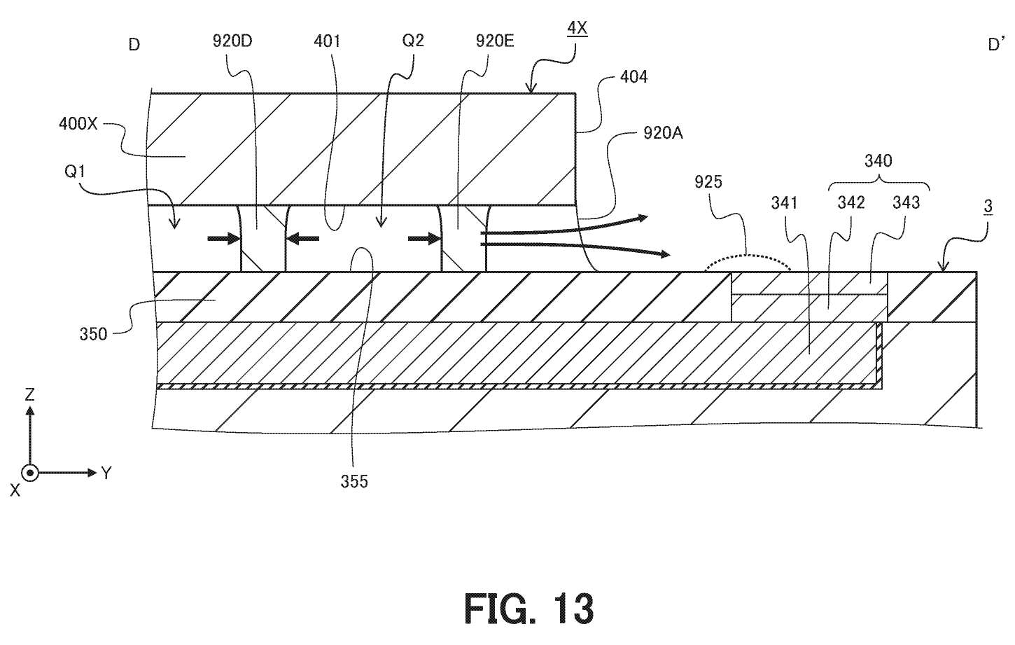

FIG. 12 is a partial top view illustrating a problem that occurs at the time of bonding a plurality of main electrodes separated by an insulating layer and a conventional metal wiring board. FIG. 13 is a sectional side view illustrating an example in which a bonding material between a semiconductor element and a conventional metal wiring board scatters. FIG. 13 illustrates a cross-sectional side surface of the joint between the semiconductor element 3 and the metal wiring board 4 at a position indicated by an alternate long and short dash line D-D’ in FIG. 12.

FIG. 12 and FIG. 13 illustrate an example in which a joint 400X in a conventional metal wiring board 4X is bonded to the emitter electrodes 320A and 320B of the semiconductor element 3. In the joint 400X, a lower surface (first main surface) 401 facing the upper surface of the semiconductor element 3 is a flat surface, and the above-described recess 410, and the first protrusion 430 and the second protrusion 440 are not formed. When such a conventional joint 400X is bonded to the emitter electrodes 320A and 320B of the semiconductor element 3 by the bonding material 920, bridges 920C, 920D, and 920E of the bonding material may occur on the insulating layer 350 between the emitter electrodes as illustrated in FIG. 12. The bridges 920C, 920D, and 920E are connected to the bonding material 920A on the first emitter electrode 320A and the bonding material 920B on the second emitter electrode 320B. In some cases, as illustrated in FIG. 13, the bridges 920C, 920D, and 920E are in contact with the upper surface 355 of the insulating layer 350 and the lower surface 401 of the joint 400X to generate sealed spaces Q1 and Q2 between the insulating layer 350 and the joint 400X. In the examples of FIG. 12 and FIG. 13, the first sealed space Q1 is generated by the first bridge 920C and the second bridge 920D, and the second sealed space Q2 is generated by the second bridge 920D and the third bridge 920E. Heating in a process of bonding the metal wiring board 4X to the emitter electrodes 320A and 320B of the semiconductor element 3 expands the air in the sealed spaces Q1 and Q2. When the air in the sealed spaces Q1 and Q2 expands, the bridges (bonding material) 920C, 920D, and 920E may be pushed in the direction along the extending direction of the insulating layer 350 and scatter outside the bonding region with the metal wiring board 4X on the upper surface of the semiconductor element 3. For example, when the bridge 920E located at a position close to one end (other end 404) in the extending direction of the insulating layer 350 in the joint 400X of the metal wiring board 4X shown in FIG. 13 scatters, the bridge 920E may adhere onto the control electrode 340 like a scattering object (bonding material) 925 indicated by a dotted line. The control electrode 340 may be a laminate of metal layers 342 and 343 laminated on one end portion of the control signal line (gate runner) 341 illustrated in FIG. 13 in the extending direction but is not limited to such a two-layer laminate. The control electrode 340 is formed using, for example, the same material as the emitter electrodes 320A and 320B. The scattering object 925 on the control electrode 340 may cause, for example, a bonding failure between one end of the bonding wire 5 (refer to FIG. 1) and the control electrode 340. In addition, if the scattered bonding material adheres to and remains in other portions, it may cause malfunction of the semiconductor device 1 or deterioration of reliability.

In addition, for example, as in WO 2019/244492 A and JP 2025-014321 A, when a recess is provided at a position facing the insulating layer between the emitter electrodes of the semiconductor element on the lower surface of the joint in the metal wiring board, a portion of the melted bonding material on the insulating layer flows into the recess, and the other portion flows out to the side of the emitter electrode. For this reason, a void that is not filled with the bonding material may be generated in the recess, and the generated void may be sealed by a bridge of the bonding material to generate a sealed space similar to the sealed spaces Q1 and Q2 described above with reference to FIG. 12 and FIG. 13. In addition, when a protrusion is provided at a position separated from the boundary between the emitter electrode of the semiconductor element and the insulating layer (gate runner) on the lower surface of the joint in the metal wiring board as in WO 2021/075220 A, it is difficult to prevent a bridge of the bonding material from being formed on the insulating layer by the protrusion.

On the other hand, in the metal wiring board 4 according to the present embodiment, the first protrusion 430 and second protrusion 440 provided along the recess 410 facing the insulating layer 350 of the semiconductor element 3 in the first joint 400 prevent (suppress) the melted bonding material 920 from filling the recess 410. Therefore, by using the metal wiring board 4 according to the present embodiment, as shown in FIG. 5 and FIG. 6, the air passage P communicating from one end 403 to the other end 404 in the extending direction of the insulating layer 350 can be reliably generated in the recess 410 of the joint 400 on the insulating layer 350 between the emitter electrodes 320A and 320B of semiconductor element 3. Therefore, it is possible to prevent the sealed space from being generated by the bridge of the bonding material as described above with reference to FIG. 12 and FIG. 13, and it is possible to prevent malfunction of the semiconductor device 1 and deterioration of reliability due to scattering of the bonding material due to expansion of air in the sealed space.

In addition, by bringing the protrusions 430 and 440 provided on the lower surface of the joint 400 into contact with the upper surface of the semiconductor element 3, the thicknesses of the bonding materials 920A and 920B can be easily controlled, and variations in the thicknesses of the bonding materials 920A and 920B for each semiconductor device 1 can be reduced. For this reason, for example, it is possible to easily prevent variations in bonding reliability due to variations in the thicknesses of the bonding materials 920A and 920B for each semiconductor device 1.

Further, in the metal wiring board 4 according to the present embodiment, for example, partial plating for improving solder wettability may be formed on the lower surface (first main surface) of the joint 400 as in JP 2009-054690 A. In this example, the partial plating can be formed, for example, on the bonded surface 401A facing the first emitter electrode 320A and the bonded surface 401B facing the second emitter electrode 320B of the semiconductor element 3 on the lower surface of the joint 400. In this way, the melted bonding material 920 located below the first protrusion 430 and the second protrusion 440 easily flows to the bonded surfaces 401A and 401B, and the amount of the bonding material entering the recess 410 can be further reduced. Therefore, the air passage P communicating from the one end 403 to the other end 404 in the extending direction of the insulating layer 350 in the recess 410 of the joint 400 can be more reliably generated on the insulating layer 350 between the emitter electrodes of the semiconductor element 3.

In the semiconductor element 3 that bonds the metal wiring board 4 according to the present embodiment, the relationship between the upper surfaces of the emitter electrodes 320A and 320B and the upper surface 355 of the insulating layer 350 is not limited to the relationship in a single plane as illustrated in FIG. 5 and FIG. 6. In other words, the upper surface of the semiconductor element 3 may have a step at the boundary between the upper surfaces of the emitter electrodes 320A and 320B and the upper surface 355 of the insulating layer 350. In addition, the planar shape of the insulating layer 350 in the semiconductor element 3 is not limited to a shape in which the width W12 of the second section 352 located at the central portion in the extending direction is greater than the width W11 of the first section 351 and the third section 353 adjacent to the second section 352. The insulating layer 350 of the semiconductor element 3 may have a single width from one end to the other end in the extending direction. In addition, the insulating layer 350 of the semiconductor element 3 may be divided into four or more sections having different widths of adjacent sections.

In the metal wiring board 4 according to the present embodiment, the width W31 of the recess 410, the width W41 of the first protrusion 430, the width W42 of the second protrusion 440, and the spacing W32 between the first protrusion 430 and the second protrusion 440 provided on the lower surface of the first joint 400 are not limited to specific values. For example, the spacing W32 between the first protrusion 430 and the second protrusion 440 may be larger or smaller than the width W11 of the first section 351 and the third section 353 in the insulating layer 350 between the emitter electrodes 320A and 320B of the semiconductor element 3. From the viewpoint of suppressing generation of a sealed space on the insulating layer 350 by the bonding material entering the recess 410, the spacing W32 between the first protrusion 430 and the second protrusion 440 is preferably large. Further, the spacing W32 between the first protrusion 430 and the second protrusion 440 may be different from the width W31 of the recess 410. In addition, when the first protrusion 430 and the second protrusion 440 are in direct contact with the emitter electrodes 320A and 320B of the semiconductor element 3, it is preferable to reduce contact areas thereof from the viewpoint of suppressing an increase in contact resistance. In addition, the dimension of each part can be set according to processing accuracy when the recess 410 is formed on the lower surface of the first joint 400, processing conditions when the first protrusion 430 and the second protrusion 440 are joined (bonded) to the lower surface of the first joint 400, and the like.

### Second Embodiment

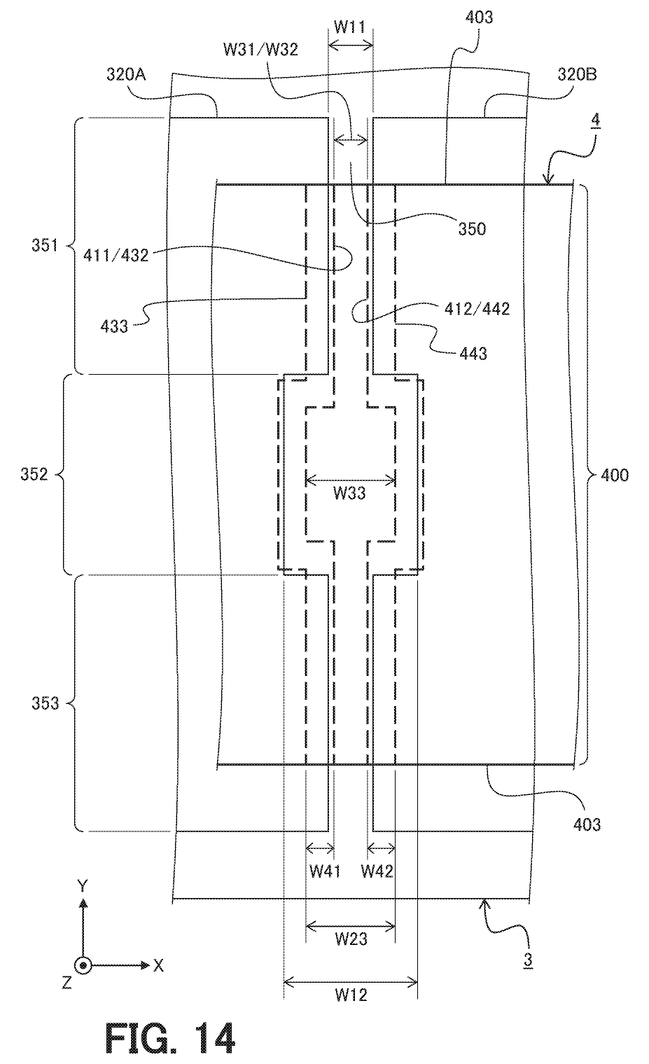

FIG. 14 is a top view illustrating a relationship between the insulating layer between the main electrodes of the semiconductor element according to a second embodiment and the recess and the protrusions of the metal wiring board. The semiconductor element 3 in the semiconductor device 1 according to the second embodiment can have the same configuration as the semiconductor element 3 exemplified in the first embodiment. For example, as shown in FIG. 14, the insulating layer 350 between the first emitter electrode 320A and the second emitter electrode 320B is divided into three sections 351, 352, and 353 in the extending direction (Y direction). Among the three sections 351, 352, and 353, the width W12 of the second section 352 located at the central portion in the extending direction (Y direction) is greater than the width W11 of the adjacent first section 351 and third section 353.

In the metal wiring board 4 in the semiconductor device 1 according to the second embodiment, the recess 410, the first protrusion 430, and the second protrusion 440 are provided on the lower surface of the first joint 400 (the first main surface facing the upper surface of the semiconductor element 3). In the metal wiring board 4 according to the present embodiment, as shown in FIG. 14, the tendency of change in the width of the recess 410 in the extending direction corresponds to the tendency of change in the width of the insulating layer 350 of the semiconductor element 3. Specifically, the recess 410 has a section with a second distance (width W33) greater than a first distance between two sections where the distance from one wall surface 411 to the other wall surface 412 is the first distance (width W31). The width W31 of the recess 410 may be substantially the same as the width W11 of the first section 351 and the third section 353 of the insulating layer 350. The width W31 of the recess 410 is greater than the width W11 of the first section 351 and the third section 353 of the insulating layer 350 and less than the width W12 of the second section 352 of the insulating layer 350. In this example, the first protrusion 430 and the second protrusion 440 are formed in a shape in which the distance from the inner side surface 432 to the inner side surface 442 at each position in the extending direction is substantially the same as the distance from the wall surface 411 to the wall surface 412 of the recess 410. In the first protrusion 430 and the second protrusion 440 shown in FIG. 14, the tendency of change in the distance from the outer side surface 433 to the outer side surface 443 at each position in the extending direction corresponds to the tendency of change in the distance from the inner side surface 432 to the inner side surface 442. Specifically, the first protrusion 430 and the second protrusion 440 have a section with a fourth distance greater than a third distance W23 between two sections where the distance from the outer side surface 433 to the outer side surface 434 is the third distance W23. The fourth distance may be substantially the same (for example, the distance W22 illustrated in FIG. 7) as the width W12 of the second section 352 in the insulating layer 350 of the semiconductor element 3.

The metal wiring board 4 illustrated in FIG. 14 has the recess 410 having a larger volume than the recess 410 of the metal wiring board 4 illustrated in the first embodiment by the amount of the wide section provided in the central portion of the recess 410 in the extending direction. Therefore, the melted bonding material is less likely to fill the recess 410 than in the first embodiment. In addition, the outer side surface 433 of the first protrusion 430 and the outer side surface 443 of the second protrusion 440 have sections on both sides of a section where the distance between the sides in the extension direction is substantially the same as the width W12 of the second section 352 of the insulating layer 350, where the distance decreases. Therefore, in the metal wiring board 4 of the second embodiment, the contact area between the first protrusion 430 and the first emitter electrode 320A and the contact area between the second protrusion 440 and the second emitter electrode 320B can be reduced as compared with the first embodiment. Therefore, it is possible to suppress an increase in contact resistance due to direct contact between the protrusions 430 and 440 of the metal wiring board 4 and the emitter electrodes 320A and 320B of the semiconductor element 3.

The recess 410, the first protrusion 430, and the second protrusion 440 in the metal wiring board 4 according to the second embodiment are not limited to the shapes described above with reference to FIG. 14. The first protrusion 430 and the second protrusion 440 according to the second embodiment may be formed in a shape in which the distance between the inner side surfaces 432 and 442 is greater than both end portions at the central portion in the extending direction as illustrated in FIG. 14, and the distance between the outer side surfaces 433 and 443 is constant from one end to the other end in the extending direction as illustrated in FIG. 7. In this example, the recess 410 may have a shape in which the width (distance from one wall surface 411 to the other wall surface 412) is greater than both end portions at the central portion in the extending direction as illustrated in FIG. 14, or may have a constant shape from one end to the other end in the extending direction as illustrated in FIG. 7. Furthermore, the first protrusion 430 and the second protrusion 440 according to the second embodiment may be formed in a shape in which the distance between the inner side surfaces 432 and 442 is constant from one end to the other end in the extending direction as exemplified in FIG. 7, and the distance between the outer side surfaces 433 and 443 is greater than both end portions at the central portion in the extending direction as exemplified in FIG. 14.

### Third and Fourth Embodiments

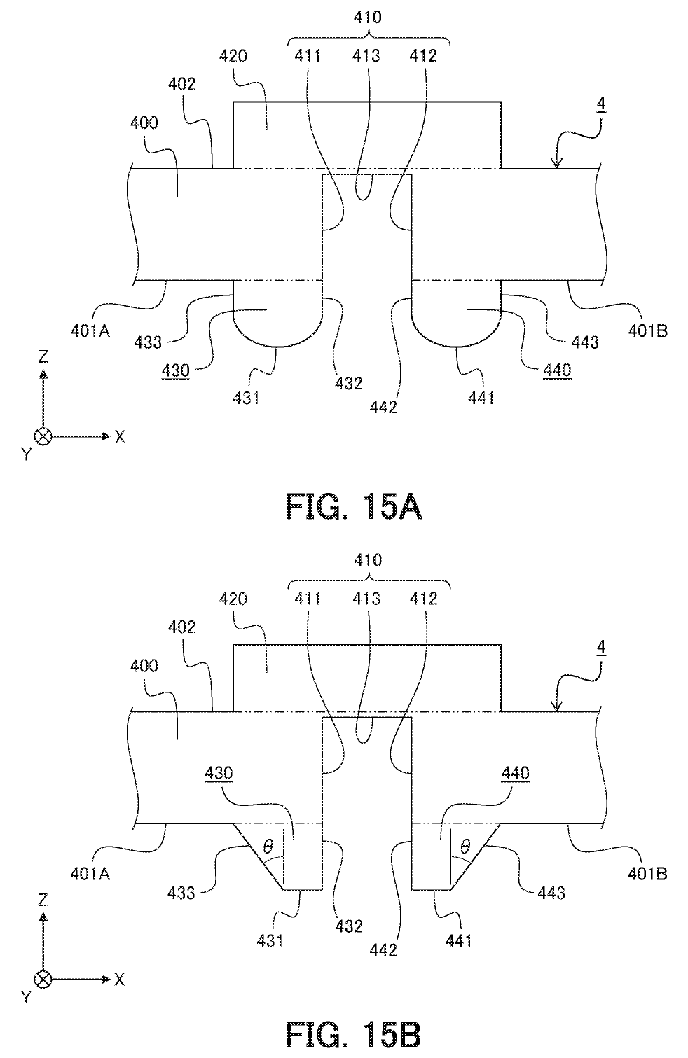

FIG. 15A is a front view illustrating an example of the shape of the protrusion of the metal wiring board according to a third embodiment, and FIG. 15B is a front view illustrating an example of the shape of the protrusion of the metal wiring board according to a fourth embodiment.

In the metal wiring board 4 according to the embodiment, the protrusions 430 and 440 provided on the lower surface of the first joint 400 are not limited to having a rectangular cross section. For example, as illustrated in FIG. 15A, the protrusions 430 and 440 may be formed such that the distal end surfaces 431 and 441 are convex curved surfaces. In the protrusions 430 and 440 in this example, any one or both of the inner side surfaces 432 and 442 and the outer side surfaces 433 and 443 may have a convex curved surface shape continuous from the distal end surfaces 431 and 441 instead of a flat surface. In a case where the distal end surfaces 431 and 441 are convex curved surfaces, for example, the shape can prevent damage of the insulating layer 350 and reduce the contact area between the protrusions 430 and 440 (metal wiring board 4) and the emitter electrodes 320A and 320B when the distal end surfaces 431 and 441 are in contact with the upper surface (that is, the emitter electrodes 320A and 320B) of the semiconductor element 3 outside the insulating layer 350 on the upper surface of the semiconductor element 3, which is preferable.

Further, the protrusions 430 and 440 provided on the lower surface of the first joint 400 may have a trapezoidal cross section. In this example, as illustrated in FIG. 15B, the protrusions 430 and 440 can have the outer side surfaces 433 and 443 as inclined surfaces having a gradient θ so as to be tapered in the protruding direction (-Z direction) of the protrusion. The gradient θ is not limited to a specific angle.

When the protrusions 430 and 440 of the metal wiring board 4 illustrated in FIG. 15A and FIG. 15B enter the melted bonding material 920 from the distal end surfaces 431 and 441 in the bonding process, the bonding material 920 is pushed out toward the bonded surfaces 401A and 401B along the convex curved surfaces or the inclined outer side surfaces 433 and 443. Therefore, as compared with a case where the protrusions 430 and 440 having a rectangular cross section are provided, extrusion of the melted bonding material 920 toward the bonded surfaces 401A and 401B is promoted, and the amount of the bonding material 920 entering the recess 410 can be further reduced. In addition, the protrusions 430 and 440 of the metal wiring board 4 illustrated in FIG. 15A and FIG. 15B can reduce the contact area with the upper surface of the semiconductor element 3 as compared with a case where the cross section is rectangular. Therefore, it is possible to suppress an increase in contact resistance due to direct contact between the protrusions 430 and 440 of the metal wiring board 4 and the emitter electrodes 320A and 320B of the semiconductor element 3.

The protrusions 430 and 440 of the metal wiring board 4 are not limited to the shapes described above. For example, as illustrated in FIG. 15B, in the protrusions 430 and 440 having the outer side surfaces 433 and 443 as inclined surfaces, the distal end surfaces 431 and 441 may be convex curved surfaces. Further, the protrusions 430 and 440 having a trapezoidal cross section are not limited to the right-angled trapezoidal shape illustrated in FIG. 15B, and may have a shape such as an isosceles trapezoidal shape in which the inner side surfaces 432 and 442 are inclined such that the distance between the inner side surfaces 432 and 442 increases in the protruding direction of the protrusion. Further, the cross sections of the protrusions 430 and 440 may have a shape tapered from a predetermined position between the distal end surfaces 431 and 441 and the boundary surface between the bonded surfaces 401A and 401B toward the distal end surfaces 431 and 441.

### Fifth Embodiment

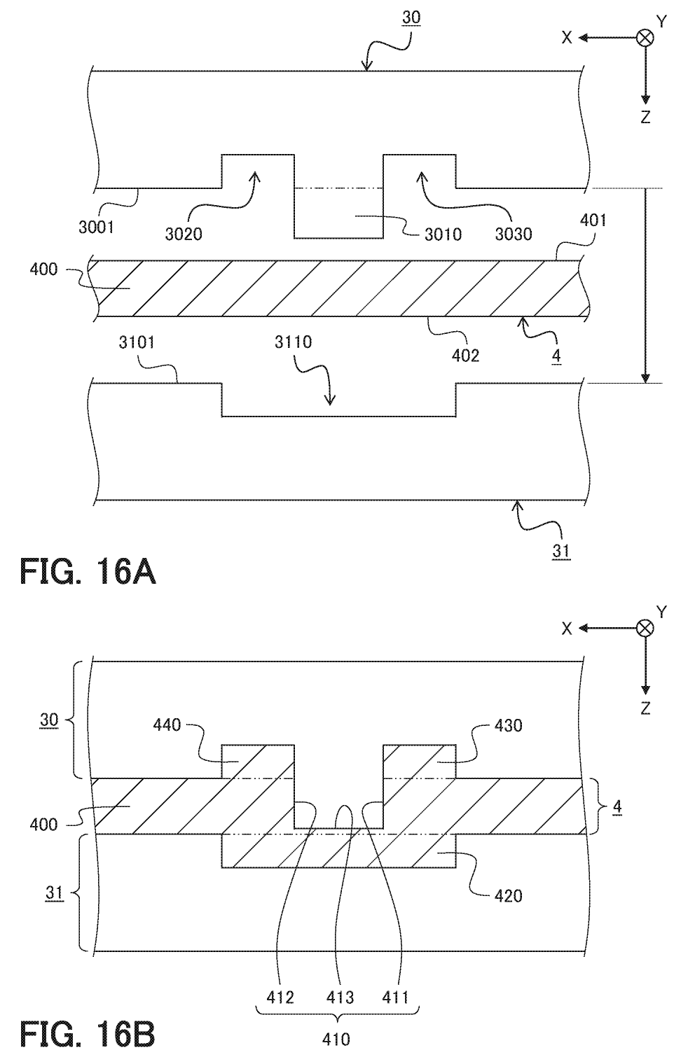

FIG. 16A and FIG. 16B are cross-sectional views illustrating an example of a method of forming the metal wiring board according to a fifth embodiment. In FIG. 16A and FIG. 16B, hatching of the upper mold 30 and the lower mold 31 is omitted. The method of forming the first protrusion 430 and the second protrusion 440 in the first joint 400 in the metal wiring board 4 is not limited to the method of bonding the rod-shaped members 430’ and 440’ provided separately from the metal wiring board 4 as described above with reference to FIG. 9 to the metal wiring board 4. The first protrusion 430 and the second protrusion 440 may be integrally formed with the metal wiring board 4 by press molding or the like. For example, as shown in FIG. 16A, a recess 3020 and a recess 3030 corresponding to the protrusions 430 and 440 of the metal wiring board 4 are provided together with a protrusion 3010 corresponding to the recess 410 on the lower surface 3001 of the upper mold 30 for providing the recess 410 in the metal wiring board 4. When the flat plate-shaped metal wiring board 4 is disposed between the upper mold 30 and the lower mold 31 and clamped, a portion of the metal wiring board 4 into which the protrusion 3010 of the upper mold 30 is pushed is displaced into the adjacent recesses 3020 and 3030 of the upper mold 30 and the recess 3110 of the lower mold 31 and molded. At this time, portions molded in the recesses 3020 and 3030 of the upper mold 30 become the protrusions 430 and 440 of the metal wiring board 4, and a portion molded in the recess 3110 of the lower mold 31 becomes the protrusion 420 protruding from the upper surface 402 of the first joint 400. The method of integrally forming the first protrusion 430 and the second protrusion 440 on the metal wiring board 4 is not limited to press molding. For example, the first protrusion 430 and the second protrusion 440 may be formed by cutting a surface to be the lower surface of the first joint 400 in the conductor plate used to form the metal wiring board 4. In this example, the recess 410 may be formed by further cutting between the first protrusion 430 and the second protrusion 440. The metal wiring board 4 having the recess 410 and the protrusions 430 and 440 in the first joint 400 can also be formed by, for example, a metal 3D printer.

### Sixth Embodiment

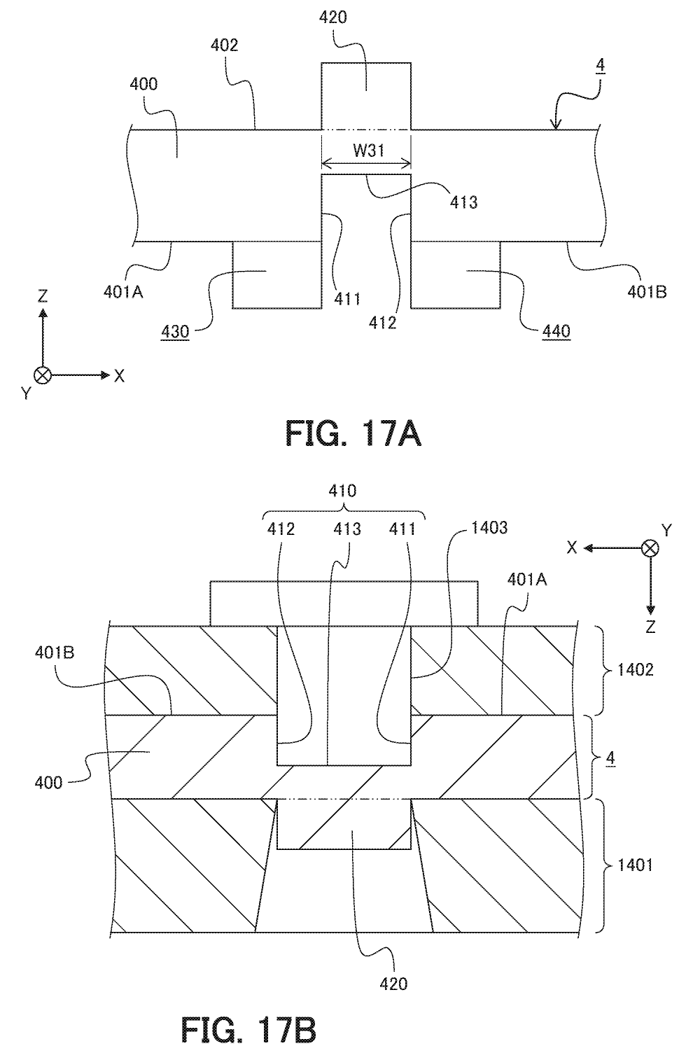

FIG. 17A is a front view illustrating an example of a shape of the metal wiring board according to a sixth embodiment, and FIG. 17B is a cross-sectional view illustrating an example of a method of forming the metal wiring board according to the sixth embodiment. In the metal wiring board 4 according to the above-described embodiment, as shown in FIG. 8 and the like, the width (dimension in the X direction) W4 of the protrusion 420 protruding upward from the upper surface (second main surface) 402 of first joint 400 is greater than the width W31 of the recess 410. Such a shape may be advantageous for deepening the recess 410. However, the relationship between the width W31 of the recess 410 and the width (width W4 in FIG. 8) of the protrusion 420 is not limited to such a relationship. For example, as shown in FIG. 17A, the width of the protrusion 420 provided on the upper surface 402 of the first joint 400 may be substantially the same as the width W31 of the recess 410. The recess 410 of the metal wiring board 4 illustrated in FIG. 17A can be formed by, for example, half punching (half cutting) using a die (punching die) as illustrated in FIG. 17B. The half punching is processing in which the first joint 400 of the metal wiring board 4 is clamped between a die 1401 and a stripper 1402, and a punch 1403 is pushed into the first joint 400 to such an extent that no hole is formed in the first joint 400 to deform the first joint. In the first joint 400, only a portion pressed by the punch 1403 is displaced downward to form the protrusion 420 on the side opposite to the recess 410.

### Seventh Embodiment

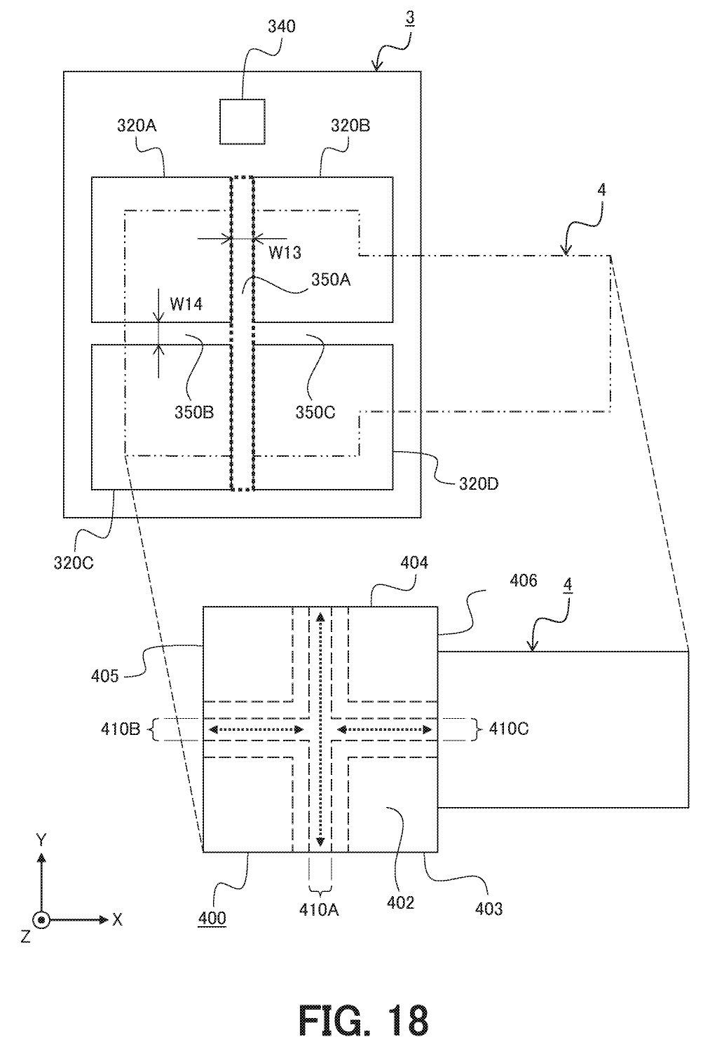

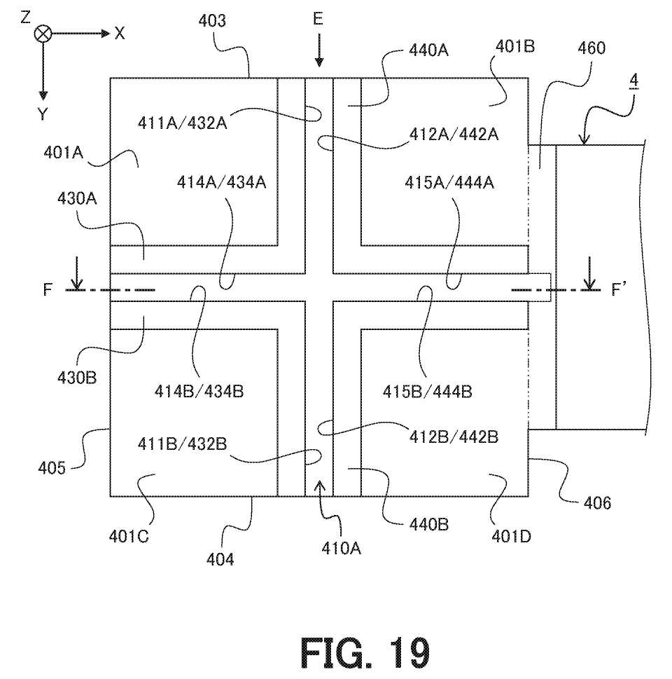

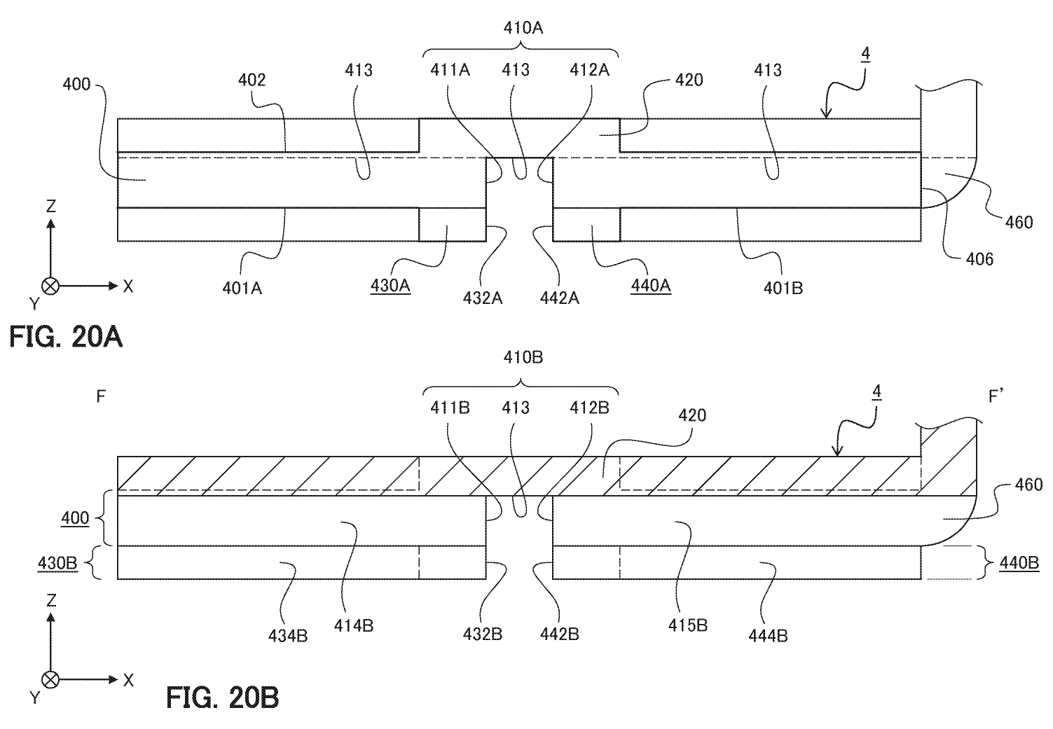

FIG. 18 is an exploded top view illustrating a relationship between the main electrodes of the semiconductor element and the metal wiring board according to a seventh embodiment. FIG. 19 is a bottom view illustrating a configuration example of a first main surface of the metal wiring board according to the seventh embodiment. FIG. 20A is a view of the metal wiring board as viewed from an arrow E in FIG. 19, and FIG. 20B is a cross-sectional side view of the metal wiring board at a position indicated by a dashed dotted line F-F’ in FIG. 19.

The main electrode (emitter electrode 320) of the semiconductor element 3 bonded to the first joint 400 of the metal wiring board 4 is not limited to the main electrode divided into two. In the present embodiment, the case illustrated in FIG. 18 where the emitter electrodes 320A to 320D divided into four parts by the insulating layer having a cross planar shape are exposed on the upper surface of the semiconductor element 3 will be described as an example. The cross-shaped insulating layer includes a first insulating layer 350A extending in the Y direction, and a second insulating layer 350B and a third insulating layer 350C extending in opposite directions from a central portion of the first insulating layer 350A in the extending direction. The dimension (width) W13 of the first insulating layer 350A in the X direction orthogonal to the extending direction may be, for example, substantially the same as the width W11 of the first section 351 of the insulating layer 350 described above with reference to FIG. 7 and the like. The dimension (width) W14 of the second insulating layer 350B and the third insulating layer 350C in the Y direction orthogonal to the extending direction may be, for example, substantially the same as the width W11 of the first section 351 of the insulating layer 350 described above with reference to FIG. 7 and the like. The dimension W13 of the first insulating layer 350A may be different from the dimension W14 of the second insulating layer 350B and the third insulating layer 350C.

In the first joint 400 of the metal wiring board 4 bonded to the four divided emitter electrodes 320A to 320D of the semiconductor element 3, for example, as illustrated in FIG. 18 and FIG. 19, cross-shaped recesses corresponding to the cross-shaped insulating layers 350A to 350C of the semiconductor element 3 are formed. The cross-shaped recesses include a first recess 410A extending in the Y direction, and a second recess 410B and a third recess 410C extending in opposite directions from a central portion of the first recess 410A in the extending direction. The first recess 410A extends from one end 403 to the other end 404 of the recess 410A in the extending direction in the first joint 400. One end of the second recess 410B communicates with the first recess 410A, and the other end extends to an end 405 of the first joint 400 in the extending direction (-X direction) of the recess 410B. One end of the third recess 410C communicates with the first recess 410A, and the other end extends to an end 406 of the first joint 400 in the extending direction (+X direction) of the recess 410C. The end 406 of the first joint 400 is connected to a bent portion 460, and the third recess 410C reaches a surface continuous with the lower surface of the first joint 400 in the bent portion 460 as illustrated in FIG. 19 and FIG. 20B. The bent portion 460 is a bent portion adjacent to the first joint 400 in the metal wiring board 4.

As shown in FIG. 19, the lower surface (first main surface) of the first joint 400 has bonded surfaces 401A to 401D divided into four by the cross-shaped recesses 410A to 410C. Protrusions 430A, 430B, 440A, and 440B are provided in an L-shaped region along the recesses in the four bonded surfaces 401A, 401B, 401C, and 401D. As illustrated in FIG. 19 and FIG. 20A, the first bonded surface 401A and the second bonded surface 401B are separated by the first recess 410A. The first recess 410A includes a pair of wall surfaces 411A and 412A and a bottom surface 413. The wall surface 411A is connected to the inner side surface 432A of the first protrusion 430A, and the wall surface 412A is connected to the inner side surface 442A of the second protrusion 440A. The distance between the wall surfaces 411A and 412A and the distance between the inner side surfaces 432A and 442A may be, for example, substantially the same as the width W13 of the first insulating layer 350A of the semiconductor element 3.

The wall surfaces 414A and 414B constituting the second recess 410B between the first bonded surface 401A and the third bonded surface 401C are connected to the inner side surface 434A of the first protrusion 430A and the inner side surface 434B of the third protrusion 430B, respectively. The distance between the wall surfaces 414A and 414B of the second recess 410B and the distance between the inner side surfaces 434A and 434B may be, for example, substantially the same as the width W14 of the second insulating layer 350B of the semiconductor element 3. The wall surfaces 415A and 415B constituting the third recess 410C between the second bonded surface 401B and the fourth bonded surface 401D are connected to the inner side surface 444A of the second protrusion 440A and the inner side surface 444B of the fourth protrusion 440B, respectively. The distance between the wall surfaces 415A and 415B of the third recess 410C and the distance between the inner side surfaces 444A and 444B may be, for example, substantially the same as the width W14 of the third insulating layer 350C of the semiconductor element 3. The wall surfaces 411B and 412B constituting the first recess 410A between the third bonded surface 401C and the fourth bonded surface 401D are connected to the inner side surface 432B of the third protrusion 430B and the inner side surface 442B of the fourth protrusion 440B, respectively. The distance between the wall surfaces 411B and 412B of the first recess 410A and the distance between the inner side surfaces 432B and 442B may be, for example, substantially the same as the width W13 of the first insulating layer 350A of the semiconductor element 3.

The metal wiring board 4 illustrated in FIG. 19, FIG. 20A, and FIG. 20B is formed, for example, by forming the cross-shaped recesses 410A to 410C on the lower surface of the first joint 400 and then bonding (joining) the L-shaped protrusions 430A, 440A, 430B, and 440B formed separately from the metal wiring board 4. As described above, the recesses and the protrusions provided on the lower surface of the first joint 400 in the metal wiring board 4 can be formed in a shape corresponding to the planar shape of the insulating layer that separates the plurality of electrodes bonded to the single metal wiring board 4 on the upper surface of the semiconductor element 3. By using the metal wiring board 4 according to the present embodiment, it is possible to prevent generation of a sealed space by a bridge of the bonding material on the insulating layer having a cross planar shape passing between adjacent emitter electrodes. Therefore, it is possible to prevent scattering of the bonding material due to expansion of air in the sealed space, and to prevent malfunction of the semiconductor device 1 and deterioration of reliability due to the scattered bonding material.

The planar shape of the recess provided on the lower surface of first joint 400 in the metal wiring board 4 is not limited to the cross shape illustrated in FIG. 18 and FIG. 19. The planar shape of the recess is changed according to the planar shape of the insulating layer that divides the main electrode on the upper surface of the semiconductor element 3.

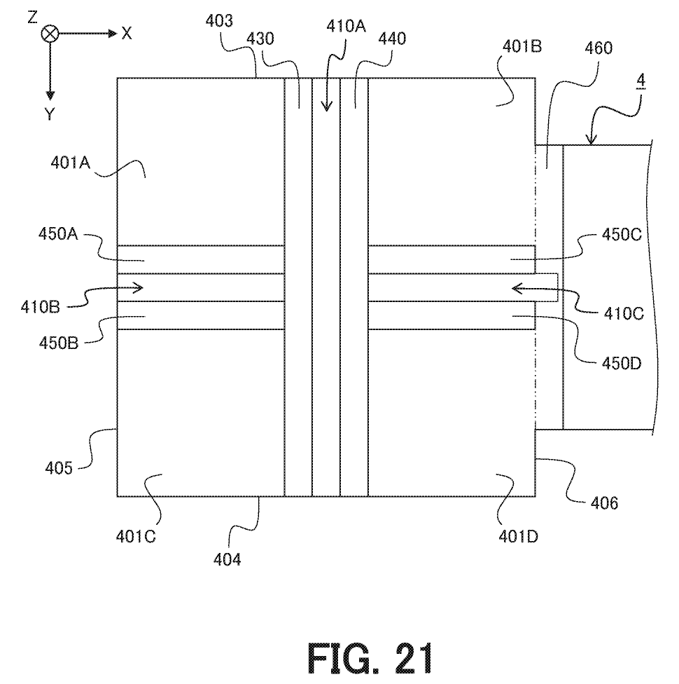

FIG. 21 is a bottom view illustrating a modified example of the metal wiring board according to the seventh embodiment. FIG. 21 illustrates a modified example of the configuration of the lower surface of the first joint 400 in the metal wiring board 4 bonded to the emitter electrodes 320A to 320D divided into four by the cross-shaped insulating layers 350A to 350C illustrated in FIG. 18. In the recesses 410A to 410C provided on the lower surface of the first joint 400, as illustrated in FIG. 21, the second recess 410B and the third recess 410C may not communicate with the first recess 410A. The first protrusion 430 extending along the first recess 410A and the pair of protrusions 450A and 450B extending along the second recess 410B may be rod-like conductive members separately formed or may be integrally formed. Similarly, the second protrusion 440 extending along the first recess 410A and the pair of protrusions 450C and 450D extending along the third recess 410C may be rod-like conductive members separately formed or may be integrally formed. The first protrusion 430, the second protrusion 440, the pair of protrusions 450A and 450B, and the pair of protrusions 450C and 450D may be integrally formed on the lower surface of the first joint 400 by press molding or the like.

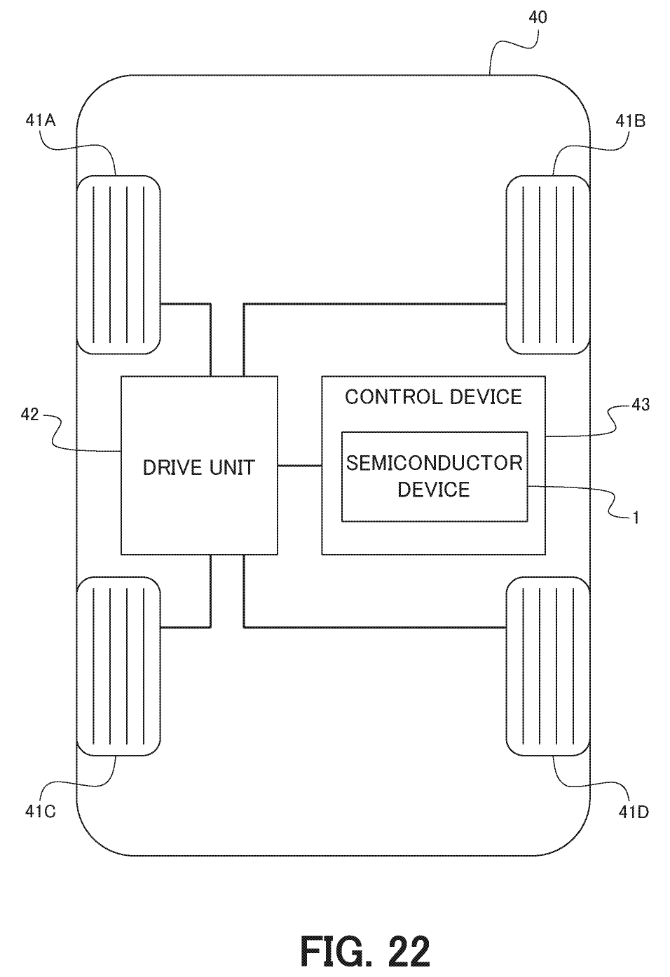

Although the semiconductor device 1 according to the above-described embodiment is not limited to a specific application, in particular, the semiconductor device 1 including the cooler 7 is suitable for use in a high-temperature environment. For example, the semiconductor device 1 of the above-described embodiment can be applied to a power conversion device such as an inverter device of an in-vehicle motor. A vehicle to which the semiconductor device 1 according to the present invention is applied will be described with reference to FIG. 22.

FIG. 22 is a schematic plan view showing an example of a vehicle to which the semiconductor device according to the present invention is applied. The vehicle 40 illustrated in FIG. 22 may be, for example, a four-wheeled vehicle including four wheels 41A to 41D. The vehicle 40 may be, for example, an electric vehicle that drives wheels by a motor, or a hybrid vehicle that uses power of an internal combustion engine in addition to the motor. The vehicle to which the semiconductor device 1 is applied is not limited to a four-wheeled vehicle, and may be a two-wheeled vehicle, a railway vehicle, or the like.

The vehicle 40 includes a drive unit 42 that applies power to the wheels 41A to 41D, and a control device 43 that controls the drive unit 42. The drive unit 42 may include, for example, at least one of a motor and a hybrid of a motor and an engine. The drive unit 42 may apply power to either the front wheels (for example, the wheels 41A and 41B) or the rear wheels (for example, the wheels 41C and 41D) among the four wheels 41A to 41D.

The control device 43 controls (for example, performs power control of) the drive unit 42. The control device 43 includes the semiconductor device 1 including the cooler 7 of the above-described embodiment. The semiconductor device 1 can be configured to perform power control on the drive unit 42.

Embodiments of the semiconductor device 1 according to the present invention are not limited to the above-described embodiments, and various changes, substitutions, and modifications may be made without departing from the spirit of the technical idea. In addition, if the technical idea can be realized in another manner by the progress of the technology or another derived technology, the technology may be implemented by using the method. Therefore, the claims cover all implementations that may be included within the scope of the technical idea.

Hereinafter, feature points in the above-described embodiments will be organized.

The semiconductor device according to the above-described embodiments includes: a semiconductor element in which a plurality of metal layers adjacent to each other with an insulating layer interposed therebetween are exposed on a first surface; and a metal wiring board having a bonded portion bonded to the plurality of metal layers of the semiconductor element via a bonding material, in which the bonded portion of the metal wiring board has a first main surface facing the first surface of the semiconductor element and a second main surface opposite to the first main surface, in which the first main surface of the bonded portion has a plurality of bonded surfaces facing the plurality of metal layers, a recess located between bonded surfaces adjacent to each other and recessed from the bonded surfaces to the side of the second main surface, and a protrusion located between the bonded surfaces and the recess and protruding from the bonded surfaces to the side of the first surface of the semiconductor element, in which the recess on the first main surface of the bonded portion extends in an extending direction of the insulating layer at a position facing the insulating layer on the first surface of the semiconductor element, the protrusion on the first main surface of the bonded portion extends along a boundary between the bonded surfaces and the recess, and a region not in contact with the bonding material within the recess is continuous from one end to another end in the extending direction in the recess.

In the semiconductor device according to the above-described embodiments, one end of the recess and the protrusion in the extending direction extends to one end of the bonded portion in the extending direction of the insulating layer of the semiconductor element.

In the semiconductor device according to the above-described embodiments, the other end of the recess in the extending direction extends to the other end of the bonded portion in the extending direction of the insulating layer of the semiconductor element.

In the semiconductor device according to the above-described embodiments, the recess includes a first recess extending in a first extending direction and a second recess communicating with the first recess and extending in a second extending direction different from the first extending direction, and each of the first recess and the second recess extends to an end of the first main surface of the bonded portion.

In the semiconductor device according to the above-described embodiments, a distal end portion of the protrusion is in contact with the first surface of the semiconductor element.

In the semiconductor device according to the above-described embodiments, the distal end portion of the protrusion has a portion in contact with the insulating layer of the semiconductor element and a portion in contact with the metal layers of the semiconductor element.

In the semiconductor device according to the above-described embodiments, the protrusion is a separate body from the bonded portion and is bonded to the bonded portion.

In the semiconductor device according to the above-described embodiments, the protrusion is integrally formed with the bonded portion.

In the semiconductor device according to the above-described embodiments, a distance between side surfaces facing each other in a pair of protrusions extending along the recess is substantially the same as a width of the insulating layer of the semiconductor element.

In the semiconductor device according to the above-described embodiments, the insulating layer of the semiconductor element has a plurality of sections having different widths, and the distance between the side surfaces of the pair of protrusions extending along the recess and facing in the opposite direction to the other protrusion is substantially the same as a largest width of the insulating layer.

The semiconductor device according to the above-described embodiments further includes a cooler thermally connected to the semiconductor element.

The vehicle according to the above-described embodiments includes the semiconductor device according to the above-described embodiments.

As described above, the present invention can prevent occurrence of malfunction of a semiconductor device due to scattering of a bonding material for bonding a main electrode of a

semiconductor element and a conductor plate, and is particularly useful for a vehicular or industrial semiconductor device used as a power conversion device, and a vehicle.

What is claimed is:

1. A semiconductor device comprising:
a semiconductor element, including:
a semiconductor layer,
a plurality of metal layers stacked on the semiconductor layer, and
an insulating layer formed between the plurality of metal layers in a top view of the semiconductor element and extending in an extending direction,
a top surface of the plurality of metal layers and the insulating layer being a first surface of the semiconductor element; and
a metal wiring board having a bonded portion bonded to the plurality of metal layers of the semiconductor element via a bonding material, wherein
the bonded portion of the metal wiring board has:
a first main surface facing the first surface of the semiconductor element, and
a second main surface opposite to the first main surface,
the bonded portion further has, on the first main surface:
a bonded surface facing the plurality of metal layers;
a recess formed in the bonded surface to separate the bonded surface into a plurality of bonded surface portions, and
a protrusion located immediately adjacent to the recess and protruding from the bonded surface to the first surface of the semiconductor element,
the recess extends in the extending direction at a position facing the insulating layer on the first surface of the semiconductor element,
the protrusion extends along the recess, and
an air passage is formed within the recess and is continuous from one end to another end in the extending direction in the recess.

2. The semiconductor device according to claim 1, wherein the recess and the protrusion extends from one end of the bonded portion in the extending direction of the insulating layer of the semiconductor element.

3. The semiconductor device according to claim 2, wherein the recess extends to the other end of the bonded portion in the extending direction of the insulating layer of the semiconductor element.

4. The semiconductor device according to claim 2, wherein
the recess is a first recess, and the extending direction is a first extending direction;
the semiconductor device further has a second recess communicating with the first recess and extending in a second extending direction different from the first extending direction, and
each of the first recess and the second recess extends to an end of the first main surface of the bonded portion.

5. The semiconductor device according to claim 1, wherein a distal end portion of the protrusion is in contact with the first surface of the semiconductor element.

6. The semiconductor device according to claim 5, wherein the distal end portion of the protrusion is in contact with both the insulating layer and the metal layers of the semiconductor element.

7. The semiconductor device according to claim 1, wherein the protrusion is a body separable from the bonded portion and is bonded to the bonded portion.

8. The semiconductor device according to claim 1, wherein the protrusion is integrally formed with the bonded portion.

9. The semiconductor device according to claim 1, wherein
the protrusion is a first protrusion,
the semiconductor device further has a second protrusion immediately adjacent to the recess and protruding from the bonded surface to the first surface of the semiconductor element,
each of the first protrusion and the second protrusion has an inner surface and an outer surface opposite to each other, the inner surfaces of the first and second protrusions facing each other across the recess,
a distance between the inner surfaces of the first and second protrusions is substantially the same as a width of the insulating layer of the semiconductor element.

10. The semiconductor device according to claim 9, wherein
the insulating layer of the semiconductor element has a plurality of sections having different widths, and
a distance between the outer surfaces the first and second protrusions is substantially the same as a largest width of the insulating layer.

11. The semiconductor device according to claim 1, further comprising a cooler thermally connected to the semiconductor element.

12. A vehicle comprising the semiconductor device according to claim 11.
